(19) United States
(12) Patent Application Publication
(10) Pub. No.: US 2026/0252258 A1
(43) Pub. Date: Aug. 27, 2026

(54) APPARATUS AND AN OPERATION METHOD FOR PERFORMING A READ OPERATION IN A MEMORY DEVICE

(71) Applicant: SK hynix Inc., Icheon-si (KR)

(72) Inventor: Nam Hyun YUN, Icheon-si (KR)

(21) Appl. No.: 19/239,734

(22) Filed: Jun. 16, 2025

(30) Foreign Application Priority Data
Feb. 21, 2025 (KR) 10-2025-0022806

(51) Int. Cl. G06F 3/06

(52) U.S. Cl. CPC G06F 3/0655; G06F 3/0604; G06F 3/0679

(57) ABSTRACT

A memory system includes a memory device including a plurality of data storage areas and a controller. The controller is configured to distribute and store a plurality of first data in a first range among the plurality of data storage areas, generate a first parity corresponding to the plurality of first data, read the plurality of first data from the first range before distributing and storing a plurality of second data in a second range spaced apart from the first range by a preset distance, perform a verification operation based on the first parity, and overwrite a second parity, corresponding to the plurality of second data in a location where the first parity is stored, based on a verification result.

### CROSS-REFERENCE TO RELATED APPLICATION

This patent application claims the benefit of Korean Patent Application No. 10-2025-0022806, filed in the Korean Intellectual Property Office on Feb. 21, 2025, the entire disclosure of which is incorporated herein by reference.

### TECHNICAL FIELD

One or more embodiments of the present disclosure described herein relate to a data storage device or a memory system, and more particularly, to a data storage device and an operating method using a parity.

### BACKGROUND

A data processing system including a memory system or a data storage device has been developed to store more data in the data storage device, store data in the data storage device more quickly, and output data stored in the data storage device more quickly. Data storage devices may include non-volatile memory cells and/or volatile memory cells for storing data. Additionally, the memory cells may store multi-bit data.

### BRIEF DESCRIPTION OF THE DRAWINGS

The description herein makes reference to the accompanying drawings wherein like reference numerals refer to like parts throughout the figures.

FIG. 1 illustrates a data processing device according to an embodiment of the present disclosure.

FIG. 2 illustrates a data processing system according to an embodiment of the present disclosure.

FIG. 3 illustrates a cell array structure in a memory device according to an embodiment of the present disclosure.

FIG. 4 illustrates a redundant array of independent disks (RAID) applicable to a memory device in accordance with an embodiment of the present disclosure.

FIG. 5 illustrates data stored in units of super memory blocks in a memory device in accordance with an embodiment of the present disclosure.

FIG. 6 illustrates a plurality of write data and parity data distributed and stored in a plurality of locations in a memory device in accordance with an embodiment of the present disclosure.

FIG. 7 illustrates an operation of programming multi-bit data in accordance with an embodiment of the present disclosure.

FIG. 8 illustrates programming of multi-bit data in accordance with an embodiment of the present disclosure.

FIG. 9 illustrates an operating method of a memory system according to an embodiment of the present disclosure.

FIG. 10 illustrates a method of verifying data stored in a memory device according to an embodiment of the present disclosure.

FIG. 11 illustrates a program operation and a verification operation performed by a memory system according to an embodiment of the present disclosure.

FIG. 12 illustrates a method of using parity information of a memory system according to an embodiment of the present disclosure.

FIG. 13 illustrates a parity generation operation of a memory system according to an embodiment of the present disclosure.

FIG. 14 illustrates an operation method of a memory system according to an embodiment of the present disclosure.

FIG. 15 illustrates a data recovery operation of a memory system according to an embodiment of the present disclosure.

### DETAILED DESCRIPTION

Various embodiments of the present disclosure are described below with reference to the accompanying drawings. Elements and features of this disclosure may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. Furthermore, the terms in a claim do not foreclose the apparatus from including additional components, e.g., an interface unit, circuitry, etc.

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational, e.g., is not turned on nor activated. Examples of block/unit/circuit/component used with the “configured to” language include hardware, for example, circuits, memory storing program instructions executable to implement the operation, etc. Additionally, “configured to” can include a generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks.

As used in this disclosure, the term ‘circuitry’ or ‘logic’ refers to all of the following: (a) hardware-only circuit implementations (such as implementations in only analog and/or digital circuitry) and (b) combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘circuitry’ or ‘logic’ applies to all uses of this term in this application, including in any claims. As a further example, as used in this application, the term “circuitry” or “logic” also covers an implementation of merely a processor (or multiple processors) or portion of a processor and its (or their) accompanying software and/or firmware. The term “circuitry” or “logic” also covers, for example, and if applicable to a particular claim element, an integrated circuit for a storage device.

As used herein, the terms “first,” “second,” “third,” and so on are used as labels for nouns that they precede, and do not imply any type of ordering (e.g., spatial, temporal, logical, etc.). The terms “first” and “second” do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term “based on” is used to describe one or more factors that affect a determination. This term does not foreclose additional factors that may affect a determination. That is, a determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

Herein, a data entry, an entry of data, an item of data, or a data item may be a sequence of bits. For example, the data entry may include the contents of a file, a portion of the file, a page in memory, an object in an object-oriented program, a digital message, a digital scanned image, a part of a video or audio signal, metadata or any other entity which can be represented by a sequence of bits. According to an embodiment, the data entry may include a discrete object. According to another embodiment, the data entry may include a unit of information processed or handled for a data input/output operation. According to another embodiment, the data entry may include a unit of information within a transmission packet between two different components.

Embodiments of the present disclosure can provide a memory device, a memory system including the memory device, a controller included in the memory system, or a data processing device including the memory system.

Embodiments in the present disclosure can provide a memory system, a data processing system, and an operation process or a method, which may quickly and reliably process data into a memory device by reducing operational complexity and performance degradation of the memory system, thereby enhancing usage efficiency of the memory device.

Embodiments of the present disclosure can provide a device and a method capable of generating a parity corresponding to a preset area or range of a memory device where some of the large-capacity data is stored and performing verification of the corresponding data, based on the parity, during the write operation. During the write operation in which a voluminous amount of data is stored in the memory system, the embodiments can reduce a burden of temporarily storing data to be stored in the memory device and a parity corresponding to the data until the write operation is completed.

Further, embodiments of the present disclosure can provide a device and a method capable of improving safety and reliability of the write operation in the memory system by performing a verification operation based on a parity generated for each predetermined range of the data stored in the memory device even when the parity of the data stored in the memory device is updated in order to reduce internal resources required for generating the parity for data distributed in plural areas of the memory device.

In an embodiment, a memory system can include a memory device including a plurality of data storage areas; and a controller configured to distribute and store a plurality of first data in a first range among the plurality of data storage areas, generate a first parity corresponding to the plurality of first data, read the plurality of first data from the first range before distributing and storing a plurality of second data in a second range spaced apart from the first range by a preset distance, perform a verification operation based on the first parity, and overwrite a second parity, corresponding to the plurality of second data in a location where the first parity is stored, based on a verification result.

The plurality of first data and the plurality of second data, respectively stored in the first range and the second range, can be the same size.

The first range can include at least one page included in each of different memory dies, different memory planes, or different memory blocks.

The first parity can be a result of an exclusive OR (XOR) operation on the plurality of first data.

The first range and the second range can include at least one page included in a same memory die, a same memory plane, or a same memory block.

The preset distance can be determined based on a range of program interference or program disturb occurring in the memory device.

In the memory system, each memory cell included in the memory device can store multi-bit data. The controller can be configured to complete a plurality of program operations for distributing and storing the multi-bit data in the first range before distributing and storing the plurality of second data in the second range.

When there is no error in the plurality of first data in a result of the verification operation, the controller can be configured to store the plurality of second data in the second range in a preset distributed manner and overwrite the second parity in the location after storing the plurality of second data.

When there is an error in the plurality of first data in a result of the verification operation, the controller can be configured to store the plurality of second data in a preset distributed manner and perform a recovery operation regarding the plurality of first data before overwriting the second parity in the location.

The controller can be configured to, while recovering the plurality of first data, store the recovered plurality of first data in a first memory block other than a second memory block where the plurality of first data is stored.

The controller can be configured to generate a parity corresponding to a parity group including the plurality of first data and the plurality of second data, stored in the first range and the second range, and store the parity in the memory device.

In another embodiment, a memory system can include a memory device including an open memory block that sequentially stores a plurality of data corresponding to a plurality of program commands; and a controller configured to transmit, to the memory device, a read command for second data stored at a second location which is spaced apart from a first location in the open memory block by a preset distance to perform a verification operation on the second data, before transmitting a first program command for first data to be stored at the first location in the open memory block to the memory device.

The first data and the second data stored at the first location and the second location can have the same size.

The first location and the second location can individually include at least one page.

The preset distance can be determined based on a range of program interference or program disturb occurring in the memory device.

In the memory system, each memory cell included in the open memory block can store multi-bit data. The controller can be configured to complete a plurality of program operations for distributing and storing the multi-bit data in the second location before distributing and storing the first data in the first location.

The controller can be configured to: store a second parity related to the second data for the verification operation; and overwrite, based on a result of the verification operation, a first parity related to the first data in a location where the second parity is stored.

The controller can be configured to: distribute and store the first data in a first range of the memory device, when there is no error in the second data as a result of the verification operation, and overwrite the first parity in the location where the second parity is stored; and distribute and store the first data in the first range, when there is an error in the second data as the result of the verification operation, and perform a recovery operation on the second data before overwriting the first parity in the location where the second parity is stored.

In another embodiment, a method for operating a memory system can include determining first data to be stored in a first location in a memory device; reading second data stored in a second location spaced apart from the first location by a preset distance; checking whether the second data has an error based on a second parity associated with the second data; and storing the first data in the first location and overwriting a first parity associated with the first data in a location where the second parity is stored, when there is no error in the second data.

The method can further include recovering the second data before storing the first data in the first location, when there is an error in the second data.

The method can further include determining the preset distance based on a range of program interference or program disturb occurring in the memory device.

An embodiment described herein can provide an apparatus and a method for improving a data input/output operation of a memory system or a data processing system. Embodiments will now be described with reference to the accompanying drawings, wherein like numbers reference like elements.

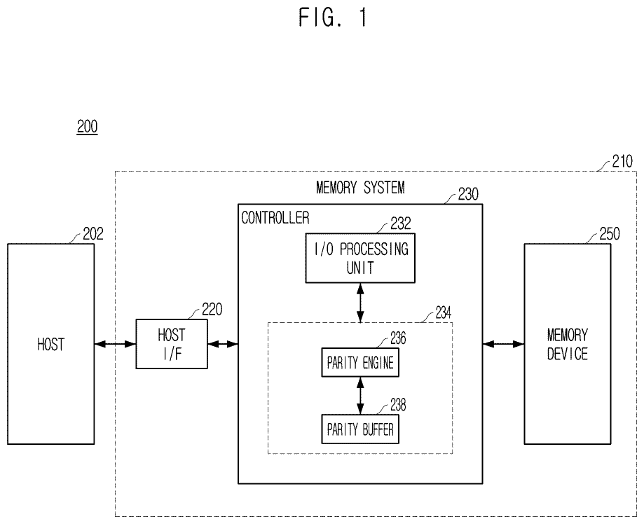

FIG. 1 illustrates a data processing device according to an embodiment of the present disclosure. Specifically, FIG. 1 is a block diagram illustrating a data processing device 200 in which a memory system 210 according to an embodiment of the present disclosure can serve as a data storage device of a host 202.

Referring to FIG. 1, the memory system 210 can include a memory device 250. The host 202 can utilize the memory device 250, including non-volatile memory cells, included in the memory system 210 to store data and retrieve stored data. For example, the memory device 250 can include at least one of any type of non-volatile memory such as MRAM, NAND, NOR, and HDD. In the following description, the memory device 250 is described as a non-volatile memory (NVM) for simplification and exemplary purposes.

The host 202 can include a host memory (e.g., DRAM). According to an embodiment, the data processing device 200 can include a plurality of storage devices, such as the memory system 210. For example, the data processing device 200 can include a plurality of memory systems 210 configured as a redundant array of independent disks (RAID) that function together as mass storage devices for the host 202. Also, according to an embodiment, the data processing device 200 can include a plurality of computing devices, such as the host 202. For example, the data processing device 200 can include the memory system 210 configured as a shared memory device that the plurality of computing devices, such as the host 202, can use for data storage and retrieval.

The data processing device 200 can include the host 202 that is capable of storing and/or retrieving data in one or more storage devices (e.g., the memory system 210). As illustrated in FIG. 1, the host 202 can perform data communication with the memory system 210 via a host interface 220. The host 202 can include a wide range of devices, including mobility electronics such as automotive, electronic devices such as cell phones or MP3 players, computer servers, network attached storage (NAS) devices, desktop computers, notebook (i.e., laptop) computers, tablet computers, set-top boxes, telephones such as “smart” phones, “smart” pads, televisions, cameras, display devices, digital media players, video game consoles, video streaming devices, and the like.

The memory system 210 can include a controller 230, the memory device 250, and the host interface 220. The controller 230 can include a data input/output processing unit 232 and a parity device 234. The parity device 234 can include a parity engine 236 and a parity buffer 238. The parity buffer 238 can include at least one memory. The at least one memory can include a volatile memory. For example, at least one memory can include a static random access memory (SRAM) and a dynamic random access memory (DRAM). The controller 230 can determine the use of the parity buffer 238 based on a data input/output operation, an operational state during the parity generation operation, a data input/output speed, or etc.

According to an embodiment, the memory system 210 can include additional components not shown in FIG. 1 for clarity. For example, the memory system 210 can include a printed circuit board (PCB) including electrically conductive wiring, etc., to which components of the memory system 210 are mechanically attached, and electrically interconnecting components of the memory system 210. In some examples, the physical dimensions and connector configurations of the memory system 210 can conform to one or more standard form factors. For example, standard form factors can include, but are not limited to, 2.5-inch data storage devices (e.g., HDD or SSD), 2.5-inch data storage devices, 1.8-inch data storage devices, peripheral component interconnect (PCI), PCI expansion (PCI-X), PCI Express (PCIe) (e.g., PCIe x1, x4, x8, x16, PCIe Mini Card, MiniPCI, etc.). According to an embodiment, the memory system 210 can be directly connected (e.g., directly soldered) to a motherboard of the host 202.

The host interface 220 of the memory system 210 can include one or both of a data bus for exchanging data with the host 202 and a control bus for exchanging commands with the host 202. The host interface 220 can operate according to any suitable protocol. For example, the host interface 220 can operate according to one or more of advanced technology attachment (ATA) (e.g., serial ATA (SATA) and parallel ATA (PATA)), universal serial bus (USB), multi-media card (MMC), fiber channel protocol (FCP), small computer system interface (SCSI), serial attached SCSI (SAS), serial advanced technology attachment (SATA), mobile industry processor interface (MIPI), PCI, PCIe, NVMe (non-volatile memory express), OpenCAPI, GenZ, Cache Coherent Interface Accelerator (CCIX), Compute Express Link (CXL), open channel solid state drive (Open Channel SSD, OCSSD), or similar protocols. An electrical connection (e.g., a data bus, a control bus, or both) of the host interface 220 can be electrically connected to the controller 230 to provide an electrical connection between the host 202 and the controller 230 to exchange data between the host 202 and the controller 230. According to an embodiment, the electrical connection of the host interface 220 can allow the memory system 210 to receive power from the host 202. For example, a power supply related device of the memory system 210 can receive power from the host 202 via the host interface 220.

The memory system 210 can include a memory device 250 including a plurality of data storage areas. According to an embodiment, the memory device 250 can be configured to store and/or retrieve data. For example, a memory die or memory chip included in the memory device 250 can receive data from the controller 230 and a message or a command instructing the memory device to store the data. Similarly, a memory die or memory chip included in the memory device 250 can receive a message from the controller 230 instructing the memory device to retrieve the data. According to an embodiment, a memory die or memory chip included in the memory device 250 can be configured to store a relatively large amount of data (e.g., 128 MB, 256 MB, 412 MB, 1 GB, 2 GB, 3 GB, 8 GB, 16 GB, 22 GB, 54 GB, 128 GB, 256 GB, 412 GB, 1 TB, etc.).

According to an embodiment, the memory device 250 can include any type of non-volatile memory device, such as a Read Only Memory (ROM), a Mask ROM (MROM), a Programmable ROM (PROM), an Erasable ROM (EPROM), an Electrically Erasable ROM (EEPROM), a Phase change RAM (PRAM), a Magnetic RAM (MRAM), a NAND or NOR flash memory, a Phase Change Random Access Memory (PCRAM), a Resistive Random Access Memory (RRAM), a Ferroelectric Random Access Memory (FRAM), a Spin Transfer Torque Magnetic Random Access Memory (STT-MRAM), a holographic memory device, a hard disk drive (HDD), and any other type of nonvolatile memory device.

According to an embodiment, the memory device 250 can include a plurality of flash memory devices. The flash memory device can include a NAND or NOR based flash memory device, and can store data based on an amount of charge contained in a floating gate of the transistor for each flash memory cell. In the NAND flash memory device, the flash memory device can be divided into a plurality of blocks, and the blocks can be divided into a plurality of pages. Each block of the plurality of blocks within a particular memory device can include a plurality of NAND cells. Rows of NAND cells can be electrically connected using word lines to establish the plurality of pages. Each cell in each of the plurality of pages can be electrically connected to a respective bit line. Additionally, the NAND flash memory device can be a 2D or 3D device. The flash memory device can include single level cells (SLC), multi-level cells (MLC), triple level cells (TLC), quad level cells (QLC), or higher level cells. The controller 230 can write and read data to and from the NAND flash memory device at the page level, and can erase data stored in the NAND flash memory device at the block level.

A portion of the memory device 250 can be formatted as a logical block, zone, or area such that a storage capacity of the memory device 250 is divided into multiple streams. Each stream can include multiple physical blocks or multiple erase blocks of the memory device 250. Each physical block can be associated with multiple logical blocks. Each logical block can be associated with a unique LBA or sector. Each stream can have a size that is tailored to a storage capacity of one or more physical blocks of the memory device 250. When the controller 230 receives a command such as from the host 202, the controller 230 can read and write data from multiple logical blocks associated with multiple physical blocks of the memory device 250.

The memory system 210 can include a power supply circuit configured to provide power to at least one component. When operating in a standard or normal mode, the power supply circuit can use power provided by an external device, such as the host 202, to power the one or more components. For example, the power supply circuit can power one or more components using power received from the host 202 via the host interface 220. According to an embodiment, the power supply circuit can include one or more power auxiliary devices configured to power one or more components when operating in a shutdown mode, such as when power input from an external device is interrupted. Examples of power auxiliary devices can include, but are not limited to, capacitors, supercapacitors, batteries, etc. According to an embodiment, the amount of power that can be stored by the one or more power storage components can correspond to a function of the cost and/or size (e.g., area/volume) of the one or more power storage components. As the amount of power stored by the one or more power storage components increases, the cost and/or size of the one or more power storage components can also increase.

The memory system 210 can also include a volatile memory device which the controller 230 may use to temporarily store data or information. The volatile memory device can include one or more volatile memories. For example, the controller 230 can use the volatile memory as a cache. The controller 230 can store cached data or information in the volatile memory until the cached data or information is completely written to the memory device 250. Examples of volatile memory can include, but are not limited to, RAM, DRAM, SRAM, and SDRAM (e.g., DDR1, DDR2, DDR3, DDR3L, LPDDR3, DDR4, LPDDR4, DDR5, LPDDR5, etc.).

Different types of volatile memories can be used with different access properties. For example, DRAM can be arranged for longer burst accesses to allow for improved bandwidth of the same access bus. Alternatively, DRAM can be used with smaller accesses so that random small accesses have better latency. The controller 230 can include additional optional SRAM and/or embedded MRAM. Embedded MRAM is another alternative memory that can be used in other embodiments. Similarly, while access to MRAM may be optimized for various design purposes, the amount of embedded MRAM in the controller 230 could be cost-sensitive. Thus, the choice of how much data and what data goes into premium non-volatile memory and premium volatile memory can be influenced by system tradeoffs.

The controller 230 within the memory system 210 can manage one or more operations of the memory system 210. For example, the data input/output processing unit 232 within the controller 230 can manage or control reading data from and/or writing data to the memory device 250. According to an embodiment, when the memory system 210 receives a write command from the host 202, the controller 230 can start processing a data write command to store data in the memory device 250 and monitor a progress of the data write command. According to an embodiment, the controller 230 can determine at least one operating characteristic of the data processing device 200 and store at least one operating characteristic in the memory device 250.

In addition, the controller 230 can include the parity device 234. The data input/output processing unit 232 can temporarily store data to be written to the memory device 250 or data read from the memory device 250 in a volatile memory. The parity device 234 can include the parity engine 236 that is configured to generate a parity for the data, temporarily stored by the data input/output processing unit 232, or verify the data, read from the memory device 250, using parity. In addition, the parity device 234 can include the parity buffer 238 used for a parity operation performed by the parity engine 236. For example, the parity buffer 238 can store the parity generated by the parity engine 236 or can store the parity used when the parity engine 236 performs a verification operation. The parity buffer 238 can be configured with at least one of DRAM and SRAM.

According to an embodiment, the parity engine 236 in the parity device 234 can be configured to perform logic and/or functions for generating XOR parity information. The XOR parity information is a type of parity and is presented for illustrative purposes. According to an embodiment, the parity engine 236 can include circuitry or engines configured to generate a type of parity other than the XOR parity information. The exclusive OR (XOR) parity information can be used to improve the stability of the memory system 210, for example, to enable data recovery from a failed data write in, or failed data read from, the memory device 250, or to enable data recovery in an event of a power off. The operational reliability of the memory system 210 can be provided based on the XOR parity information generated or calculated based on data stored in the memory system 210. For example, data stored in the memory device 250 through the data input/output processing unit 232 can be written to the memory device 250 through the parity engine 236. The parity engine 236 can store the generated parity information in the parity buffer 238.

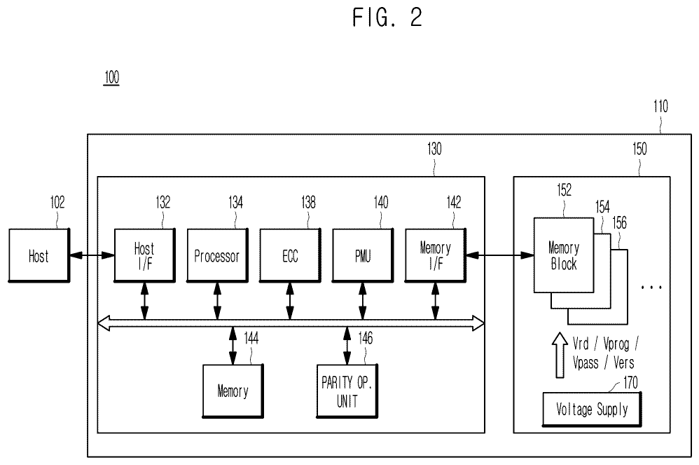

FIG. 2 illustrates a data processing system according to an embodiment of the present disclosure.

Referring to FIG. 2, a data processing system 100 may include a host 102 engaged or coupled with a memory system, such as memory system 110. For example, the host 102 and a memory system 110 can be coupled to each other via a data bus, a host cable and the like to perform data communication.

The memory system 110 may include a memory device 150 and a controller 130. The memory device 150 and the controller 130 in the memory system 110 may be considered components or elements physically separated from each other. The memory device 150 and the controller 130 may be connected via at least one data path. For example, the data path may include a channel and/or a way.

According to an embodiment, the memory device 150 and the controller 130 may be components or elements that are functionally divided. Further, according to an embodiment, the memory device 150 and the controller 130 may be implemented with a single chip or a plurality of chips.

The controller 130 may perform a data input/output operation (such as a read operation, a program operation, an erase operation, or etc.) in response to a request or a command input from an external device such as the host 102. For example, when the controller 130 performs a read operation in response to a read request input from an external device, data stored in a plurality of non-volatile memory cells included in the memory device 150 is transferred to the controller 130. Further, the controller 130 can independently perform an operation regardless of the request or the command input from the host 102. Regarding an operation state of the memory device 150, the controller 130 can perform an operation such as garbage collection (GC), wear leveling (WL), a bad block management (BBM) for checking whether a memory block is bad and handing a bad block.

The memory device 150 may include a plurality of memory blocks 152, 154, 156. The memory blocks 152, 154, 156 may be understood as a group of non-volatile memory cells in which data is removed together by a single erase operation. Although not illustrated, the memory blocks 152, 154, 156 may include a page, which is a group of non-volatile memory cells that store data together during a single program operation or output data together during a single read operation. For example, one memory block 152, 154, 156 may include a plurality of pages. The memory device 150 may include a voltage supply circuit 170 capable of supplying at least one voltage into the memory block 152, 154, 156. The voltage supply circuit 170 may supply a read voltage Vrd, a program voltage Vprog, a pass voltage Vpass, or an erase voltage Vers into a non-volatile memory cell included in the memory block 152, 154, 156.

The host 102 interworking with the memory system 110, or the data processing system 100 including the memory system 110 and the host 102, can be a mobility electronic device (such as a vehicle), a portable electronic device (such as a mobile phone, an MP3 player, a laptop computer, or the like), or a non-portable electronic device (such as a desktop computer, a game machine, a TV, a projector, or the like). The host 102 may provide interaction between the host 102 and a user using the data processing system 100 or the memory system 110 through at least one operating system (OS). The host 102 transmits a plurality of commands corresponding to user's request to the memory system 110, and the memory system 110 performs data input/output operations corresponding to the plurality of commands (e.g., operations corresponding to the user's request).

The memory system 110 may be implemented with any of various types of storage devices. Non-limiting examples of storage devices include a solid state drive (SSD), a multimedia card (MMC), an embedded MMC (eMMC), a reduced size MMC (RS-MMC), a micro-MMC, a secure digital (SD) card, a mini-SD, a micro-SD, a universal serial bus (USB) storage device, a universal flash storage (UFS) device, a compact flash (CF) card, a smart media (SM) card, a memory stick, and the like. According to an embodiment, the controller 130 may include a host interface 132, a processor 134, a power management unit (PMU) 140, a memory interface 142, and a memory 144. Components may be added to or omitted from the controller 130 according to structures, functions, operation performance, or the like, regarding the memory system 110.

The host 102 and the memory system 110 each may include a controller or an interface for transmitting and receiving signals, data, and the like, in accordance with one or more predetermined protocols. For example, the host interface 132 in the memory system 110 may include an apparatus or a circuit capable of transmitting signals, data, and the like to the host 102 or receiving signals, data, and the like from the host 102. According to an embodiment, the host interface 132 is a type of layer for exchanging data with the host 102 and is implemented with, or driven by, firmware called a host interface layer (HIL). According to an embodiment, the host interface 132 can include a command queue.

The power management unit (PMU) 140 may control electrical power provided to the controller 130. The PMU 140 may monitor the electrical power supplied to the memory system 110, e.g., a voltage supplied to the controller 130, and provide the electrical power to components included in the controller 130. The PMU 140 may not only detect power-on or power-off, but also generate a trigger signal to enable the memory system 110 to urgently back up a current state when the electrical power supplied to the memory system 110 is unstable. According to an embodiment, the PMU 140 may include a device or a component (such as Auxiliary Power Supply) capable of accumulating electrical power that may be used in an emergency.

The memory interface 142 may serve as an interface for handling commands and data transferred between the controller 130 and the memory device 150, in order to allow the controller 130 to control the memory device 150 in response to a command or a request input from the host 102. When the memory device 150 includes a NAND flash memory, the memory interface 142 includes a NAND flash controller (NFC). According to an embodiment, the memory interface 142 can be implemented through, or driven by, firmware called a Flash Interface Layer (FIL) for exchanging data with the memory device 150. Further, according to an embodiment, the memory interface 142 may support an open NAND flash interface (ONFi), a toggle mode, or the like, for data input/output with the memory device 150. For example, the ONFi may use a data path (e.g., a channel, a way, etc.) that includes at least one signal line capable of supporting bi-directional transmission and reception in a unit of 8-bit or 16-bit data. Data communication between the controller 130 and the memory device 150 can be achieved through at least one interface regarding an asynchronous single data rate (SDR), a synchronous double data rate (synchronous DDR), a toggle double data rate (toggle DDR), or the like.

The memory 144 may be used as a working memory of the memory system 110 or the controller 130, while temporarily storing transactional data for operations performed in the memory system 110 and the controller 130. According to an embodiment, the memory 144 may be implemented with a volatile memory. For example, the memory 144 may be implemented with a static random access memory (SRAM), a dynamic random access memory (DRAM), or both. The memory 144 can be disposed within the controller 130, but embodiments are not limited thereto. The memory 144 may be located within or external to the controller 130. For instance, the memory 144 may be embodied by an external volatile memory having a memory interface transferring data and/or signals between the memory 144 and the controller 130.

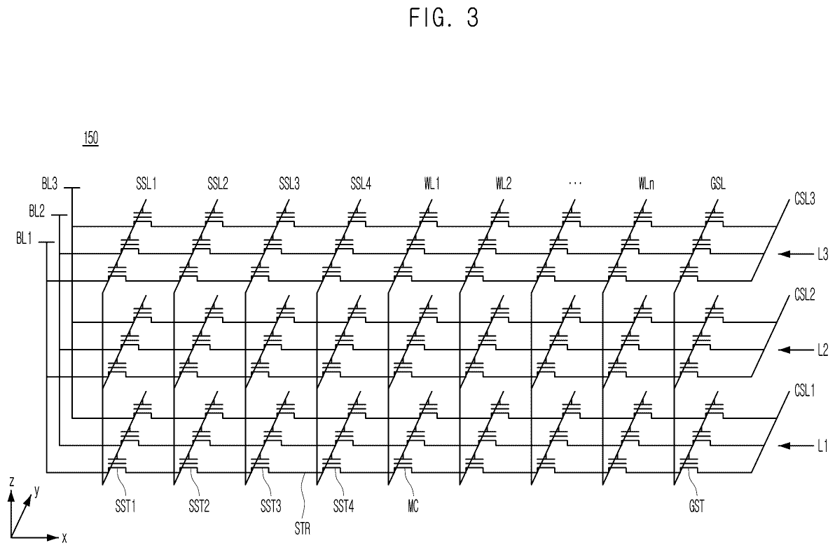

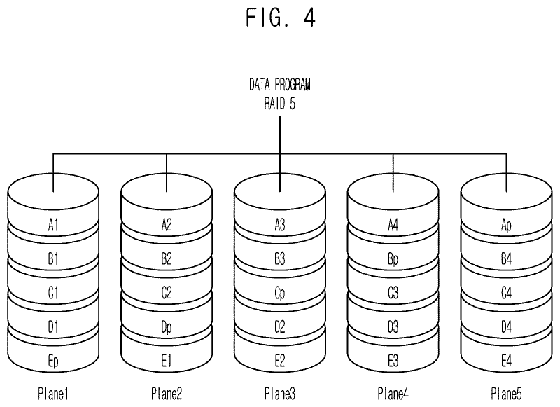

The processor 134 may control the overall operations of the memory system 110. For example, the processor 134 can control a program operation or a read operation of the memory device 150 in response to a write request or a read request entered from the host 102. According to an embodiment, the processor 134 may execute firmware to control the program operation or the read operation in the memory system 110. Herein, the firmware may be referred to as a flash translation layer (FTL). An example of the FTL will be described in detail, referring to FIGS. 3 and 4. According to an embodiment, the processor 134 may be implemented with a microprocessor, a central processing unit (CPU), or the like. According to an embodiment, the memory system 110 may be implemented with at least one multi-core processor, co-processors, or the like.

The controller 130 can include a parity operation unit 146. The parity operation unit 146 can correspond to the parity device 234 described in FIG. 1. The parity operation unit 146 can generate a parity associated with data stored in the memory device 150 or can check whether data includes an error based on the data and the parity read from the memory device 150. According to an embodiment, the parity operation unit 146 can be configured to generate a parity through various algorithms. The parity can be understood as one of the techniques used to check data accuracy in computer science and communication fields.

According to an embodiment, the memory device 150 can include a plurality of storage areas, each storage area capable of storing data. The plurality of storage areas can be operated as a Redundant Array of Independent Disks (RAID). RAID technology combines multiple storage areas or spaces into a single logical unit and distributes data across plural storage areas or spaces (e.g., plural disks) to achieve data protection, performance improvement, or both. RAID technology can reduce a risk of data loss due to hardware failure by distributing data across multiple disks (e.g., simultaneously reading or writing data from plural drives), so as to improve system performance of storage device. RAID storage comes in various “levels,” each of which may have different ways of storing and distributing data.

The parity in the RAID storage can be used primarily to increase data reliability. When storing and distributing data across plural disks using striping and adding parity blocks, the ability to recover the entire data set, even if one of the plural disks fails, can be provided to greatly improve data protection and system availability. For example, a system such as RAID 5 and RAID 6 can use parity information to recover the original data when one (or two) disks fail. According to an embodiment, parity information can be stored across the plural disks. When one disk fails, data and parity information of the remaining disks can be combined to recover lost data of the failed disk. An operation method related to a redundant array of independent disks (RAID) is described below with reference to FIG. 4.

The plurality of memory blocks 152, 154, 156 included in the memory device 150 can be distinguished according to the number of bits that can be stored or expressed in one memory cell. The memory block included in the memory device 150 can include a single level cell (SLC) memory block, a double level cell (DLC), a triple level cell (TLC), a quadruple level cell (QLC), or a multiple level cell including a plurality of pages, with each page implemented by memory cells capable of storing 5 bits or more of bit data in one memory cell.

According to an embodiment, the controller 130 can operate a multi-level cell (MLC) memory block included in the memory device 150 as an SLC memory block that stores 1-bit data in one memory cell. For example, by utilizing data input/output speeds that may be faster in some of the multi-level cell (MLC) memory blocks than in other blocks of the memory device 150, the controller 130 can use at least some of the MLC memory blocks as a SLC memory block to temporarily store data, thereby using the data as a buffer or write booster.

According to an embodiment, the controller 130 can program data multiple times in a multi-level cell (MLC) memory block included in the memory device 150 without an erase operation. In general, non-volatile memory cells may be the kind of non-volatile memory cells that do not support overwrite. However, because the MLC memory block can store multi-bit data, the controller 130 can program 1-bit data in the non-volatile memory cells multiple times. Accordingly, the number of times data is programmed into a non-volatile memory cell can be stored by the controller 130 as additional operation information. The controller 130 can also perform a uniformity operation to even the level of the threshold voltage of the non-volatile memory cell (e.g., uniform threshold voltage distribution) before reprogramming the same non-volatile memory cell.

FIG. 3 illustrates a cell array structure in a memory device according to an embodiment of the present disclosure. FIG. 3 shows non-volatile memory cells placed in three-dimensional (3D) space. Specifically, FIG. 3 illustrates a cell array in a 3D non-volatile memory device according to an embodiment of the present disclosure.

A memory device 150 may include a plurality of memory cells MC arranged in a cell string STR in a plurality of memory layers (e.g., three memory layers L1, L2, L3). Each memory layer L1, L2, L3 is connected to a plurality of bit lines BL1, BL2, BL3 through a first end of the plurality of channel lines CL and to the common source line CSL through a second end of the plurality of channel lines CL. The memory device 150 may include a plurality of source selection lines SSL1 to SSL4 connected to source select transistors SST1 to SST3. In addition, a plurality of word lines WL1 to WLn and a ground selection line GSL may be connected to each of the memory layers L1, L2, L3. The plurality of source selection lines SSL1 to SSL4, the plurality of word lines WL1 to WLn, and the ground selection line GSL may be arranged in a direction that intersects a plurality of channel lines CL. Each of the plurality of channel lines may be described as the cell string STR. Each of the cell strings STR may include the source select transistors SST1 to SST4 respectively connected to the plurality of source selection lines SSL1 to SSL4. The ground selection line GSL may be grounded to turn off the ground selection transistor GST.

The plurality of word lines WL1 to WLn may each be connected to control gates of memory cells arranged in a column direction. Each of the plurality of bit lines BL1 to BL3 may be connected to one end of the source select transistors. A plurality of memory cells having control gate electrodes connected to each word line WL1 to WLn in the row direction can configure a page, which is a unit for storing data or a data entry. The number of pages could be changed or determined depending on storage capacity of the memory cells.

As described in FIG. 3, if adjacent memory blocks are designed to share a ground selection line or cell string, a disturb effect due to a read operation or a write operation performed in a specific memory block can also affect adjacent memory cells, memory pages, or memory blocks (i.e., memory blocks in which a cell string is shared but not selected). In addition, if adjacent memory blocks are designed to share a ground selection line or cell string, a disturb effect due to a read operation or a write operation performed in a specific memory block might increase compared to a case in which the cell string is not shared. Therefore, if a write operation is performed at a specific location of the memory device 150, an error due to the disturb effect might occur in a memory cell located within a preset range at the location. In order to improve the safety and reliability of data stored in the memory device 150, it is necessary to verify an error due to the disturb effect.

FIG. 4 illustrates a redundant array of independent (or inexpensive) disks (RAID) applicable to a memory device in accordance with an embodiment of the present disclosure. Specifically, FIG. 4 shows an example of using five regions (Plane1, Plane2, Plane3, Plane4, Plane5) in a Redundant Array of Independent Disks or a Redundant Array of Inexpensive Disks (hereinafter, “RAID”).

Five regions included in the memory device using a RAID scheme can have substantially a same size. According to an embodiment, each of the five regions Plane1, Plane2, Plane3, Plane4, Plane5 included in the memory device 150 can include a memory plane, a memory block, a memory die, or the like. In another embodiment, the five regions Plane1, Plane2, Plane3, Plane4, and Plane5 can be five logical regions established by a user.

In FIG. 4, the memory system 110 can use the RAID scheme to store 4 entries of data A1, A2, A3, A4 and 1 parity Ap in five regions Plane1, Plane2, Plane3, Plane4, Plane5. Even if an error occurs in one region of the five regions Plane1, Plane2, Plane3, Plane4, Plane5, data stored in a region with errors can be recovered and restored based on the other entries of data and the parity stored in the remaining four regions. For example, the parity Ap can be generated by an exclusive-OR (XOR) logical operation on the four entries of data A1, A2, A3, A4. Thereafter, when an error occurs in a second entry of data A2 among the four entries of data A1, A2, A3, A4, the second data A2 can be recovered and restored by an exclusive-OR (XOR) operation on first, third, and fourth entries of data A1, A3, A4 and the entry of parity Ap.

In addition, because it is difficult to predict, from among the five regions Plane1, Plane2, Plane3, Plane4, Plane5, a region in which a problem will occur, locations for storing four entries of data and one entry of parity can be changed. For example, one entry of first parity Ap corresponding to the four entries of first data A1, A2, A3, A4 can stored in a fifth region Plane5, but one entry of second parity Bp corresponding to four entries of second data B1, B2, B3, B4 can be stored in a fourth region Plane4.

For generating a parity, the memory system 110 can include a parity generation engine. Referring to FIG. 4, in the five regions Plane1, Plane2, Plane3, Plane4, Plane5 of the memory device 150, four entries of first data A1, A2, A3, A4 and one entry of first parity Ap can be programmed. The parity generation engine may generate one entry of first parity Ap based on the four entries of first data A1, A2, A3, A4. In the memory system 110, four entries of first data A1, A2, A3, A4 can be stored in a first non-volatile cell region, and one entry of first parity Ap can be stored in a second non-volatile cell region. In order to program the multi-bit data, when the memory device 150 according to an embodiment of the disclosure can perform a two-step program operation, a parity can be generated and stored in the RAID scheme, and the size of the SLC buffer above described can be reduced or used efficiently.

Referring to FIG. 4, four entries of data A1, A2, A3, and A4 are used to generate one entry of parity information Ap. In order for the memory system 110 to generate one entry of parity information Ap, it must have a buffer for storing four entries of data A1, A2, A3, and A4 and one entry of parity information Ap. If the memory system 110 generates one parity based on 63 entries of data, the memory system 110 should include a buffer for storing 64 entries of data and parity.

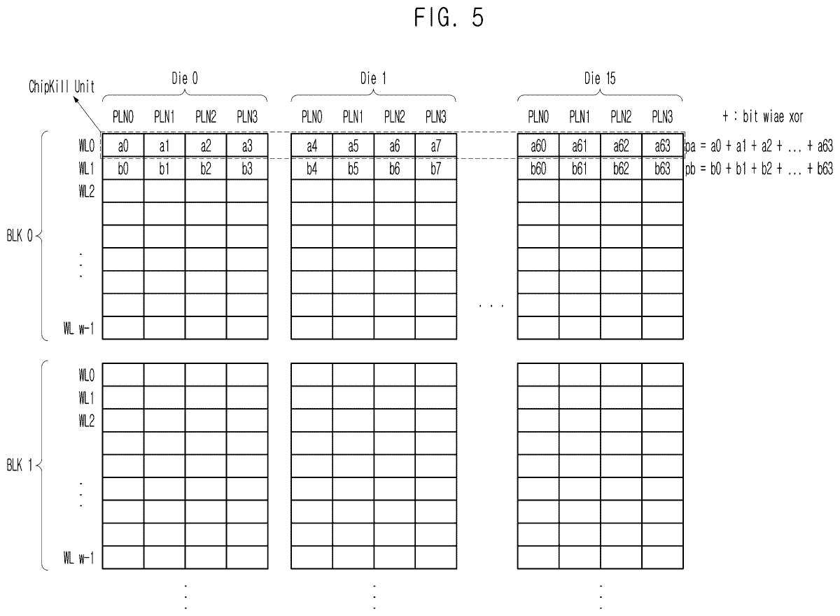

FIG. 5 illustrates data stored in units of super memory blocks in a memory device in accordance with an embodiment of the present disclosure. Specifically, FIG. 5 shows plural memory dies included the memory device 250, 150 shown in FIGS. 1 and 2. The plural memory dies are capable of storing plural data entries distributed over plural open memory blocks and a parity entry associated with the plural data entries. Herein, the plural open memory blocks can be understood as a super memory block.

Referring to FIG. 5, the memory device 250, 150 can include a plurality of memory dies Die0, Die1, . . . , Die15. Each memory die Die0 to Die15 can include four memory planes PLN0, PLN1, PLN2, PLN3. Each of the memory planes PLN0, PLN1, PLN2, PLN3 can include a plurality of memory blocks BLK0, BLK1, . . . , and each of the memory blocks BLK0, BLK1, . . . can include a plurality of memory cells connected to a plurality of word lines WL0, WL1, WL2, . . . , WLw−1.

According to an embodiment, a non-volatile memory cell of the memory device 250, 150 can store multi-bit data. However, for convenience of description, FIG. 5 shows, as an example, the memory device 250, 150 for storing a single data entry a0, a1, a2, . . . , a61, a62 or a single parity entry pa, pb in plural memory cells coupled to each word line in each memory region or area.

In order to improve the speed of the data input/output operation performed in the memory system 210, 110 shown in FIGS. 1 and 2, the memory system 210, 110 can read or program plural data entries having a preset size together or in parallel. The speed of the data input/output operation can be improved through an interleaving mode in which plural data entries of a preset size are read or programmed in parallel in plural memory areas or regions in which the data input/output operation can be performed independently or individually. In FIG. 5, data input/output operations can be independently or individually performed in each of the memory planes PLN0, PLN1, PLN2, PLN3. For example, open memory block BLK0 included in each of the plural memory planes PLN0, PLN1, PLN2, PLN3 can be included in a super memory block to be programmed with plural data entries transferred from the controller 130.

Referring to FIGS. 1-2 and FIG. 5, the memory system 210, 110 can program 63 first data entries a0, a1, a2, . . . , a61, a62 into a memory block included in 63 memory areas or regions (e.g., memory planes). In addition, the memory system 210, 110 can calculate and generate a first parity entry pa based on the 63 first data entries a0, a1, a2, . . . , a61, a62, and program the first parity entry pa in a memory area or regions other than the 63 memory areas or regions. The memory system 110 may distribute and store the 63 first data entries a0, a1, a2, . . . , a61, a62 and the first parity entry pa in 64 memory areas or regions. Herein, the 63 first data entries a0, a1, a2, . . . , a61, a62 and the first parity entry pa could be included in a single chipkill unit or a single chipkill decoding unit. Even if a UECC occurs in one of the data entries or the parity entry included in one chipkill unit, a UECC-generated data entry may be restored based on other data entries and a parity entry having no errors. According to an embodiment, the ECC unit 138 described in FIG. 2 may generate parity information corresponding to a plurality of data or recover the UECC-generated data entry based on the chipkill unit.

According to an embodiment, the parity pa, pb are not stored in the memory device and can no longer be used after the corresponding data group is successfully stored in the memory device. For example, the parity pa, pb can be used in a process of verifying that the corresponding data group is normally programmed in the memory device while programming a large amount of data.

Alternatively, according to an embodiment, the parity pa, pb can be stored in another storage device or area in the memory device. The parity pa, pb can be used to recover damaged data when the data is damaged due to a data retention period or an error or defect of the memory device after being stored in the memory device.

The memory system 210, 110 may be configured to store voluminous data. For example, 3-bit data may be stored in each of the nonvolatile memory cells in the memory device 250, 150, and eight strings may constitute one page. Further, data entries and a parity entry (total 16 entries) may be distributed and stored in 16 open memory blocks in the memory device 250, 150. The data entries may be stored in 15 open memory blocks out of 16 open memory blocks, and the parity entry may be stored in another open memory block. The number of non-volatile memory cells commonly connected to one word line of each of the 16 open memory blocks is 8 (the number of strings), and data stored in each nonvolatile memory cell is 3-bit data, so that 384(=16×8×3) bits of data and parity can be programmed in the memory device 250, 150. The memory system 210, 110 should include a buffer or a cache configured to temporarily store 384-bit data and parity so that the controller 230, 130 generates the parity entry based on the data entries during a program operation. As the number of open memory blocks in the memory device 250, 150 increases, as the number of strings increases, and as the number of bits of data stored in each non-volatile memory cell increases, the memory system 210, 110 should establish or set a larger buffer or cache for generating parity during a program operation. That is, the size of the buffer or the cache increases.

Although the above-described parity generating method and apparatus are simply implemented, the size of a buffer used for parity generation should increase as an amount of data programmed one-time in the memory device 250, 150 increases, and as a result internal resources are burdened. For example, as the memory system 210, 110 includes a larger buffer for parity generation, the production cost of the memory system 210, 110 may also increase. In the above-described parity generation method, the number of data used to generate parity is preset, and locations for storing data entries and parity entry are predetermined. Accordingly, the size of the buffer to be secured by the memory system 210, 110 to generate the parity may be determined according to a data size of the program operation and a size of the chipkill unit.

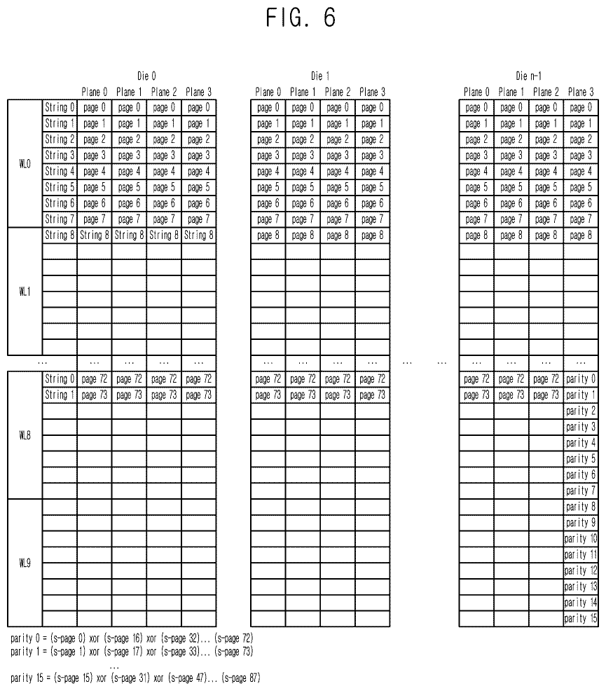

FIG. 6 illustrates a plurality of write data and parity data distributed and stored in a plurality of locations of a memory device in accordance with an embodiment of the present disclosure. Specifically, FIG. 6 shows locations where data entries are stored in memory dies Die0, Die1, Die n−1 having a structure in which eight strings String0 to String7 are coupled to each word line WL0, WL1, WL, . . . , WL9. FIG. 6 describes the parity entry generated based on the data entries. In FIG. 6, the data entries and the parity entry can be stored in plural locations of the memory dies Die0, Die1, Die n−1, which are determined in a preset distributed manner.

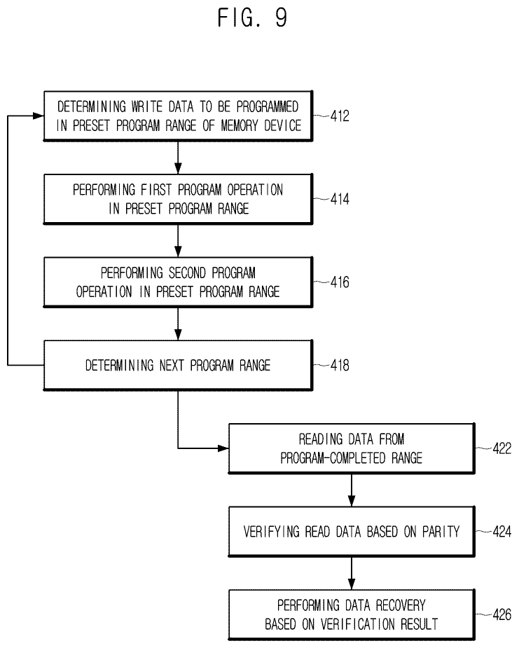

Referring to FIGS. 1 to 2 and FIG. 6, a memory device 250, 150 can include plural memory dies Die0, Die1, Die n−1. Each of the memory dies Die0, Die1, Die n−1 can include four memory planes Plane0, Plane1, Plane2, Plane3. Each word line WL0, WL1, WL, . . . , WL9 can be coupled to 8 cell strings String 0 to String 7. Although FIG. 9 shows an example of the memory device 250, 150 including 10 word lines WL0, WL1, WL, . . . , WL9, the number of word lines included in the memory device 250, 150 can vary based on storage capacity of the memory device 250, 150. A plurality of parities Parity0, Parity1, . . . , Parity15 can be generated for plural data entries which are stored at different locations in the memory device 250, 150. The plurality of parities Parity0, Parity1, . . . , Parity15 can be stored at preset locations. For example, each parity location can specify plural data locations in which data entries corresponding to a parity entry are stored.

Regarding parity generation and storage, a method shown in FIG. 6 might be similar to that shown in FIG. 5. First, based on locations of data entries stored in the memory device 250, 150, combinations of data entries for generating each parity Parity0, Parity1, . . . , Parity15 can be determined. For example, an exclusive OR (XOR) operation on a plurality of data entries s-page0, s-page16, s-page32, s-page72 stored in locations corresponding to a first string String0 coupled to the odd word lines WL0, . . . , WL8 of each plane included in the n number of memory dies can be performed to calculate a first parity parity0. The first parity parity0 may be stored in the first string String0 connected to the ninth word line WL8 in the fourth memory plane Plane3 of the n-th memory die. The other 15 parities parity1, . . . , parity15 can also be generated in the same way and stored in corresponding locations within the memory device 150.

Referring to FIG. 6, the 16 parities parity0, parity1, . . . , parity15 can be generated. The combination of data entries for generating each parity can be called a parity group. The 16 parity groups can be stored in locations corresponding to 10 word lines in the memory device 250, 150. Each parity group can correspond to 16 super-pages. Here, the super page may be a means for managing multiple locations distributed within the memory device 250, 150 as one logical page, such as a super memory group. Provided that the memory device 150 contains 100 word lines, 160 (=16×10) parity groups can be generated and stored. As the number of memory dies in the memory device 250, 150 increases (the larger the value of n), the size of data entries included in each super page increases. Also, the number of data entries included in each parity group may increase. As a result, the amount of parities (or a ratio of parities and data entries) stored in the memory device 250, 150 could be reduced, so that greater number of data entries can be stored even when the storage capacity of the memory device 150 is the same.

According to an internal configuration of the memory device 250, 150 or a set of the parity group, the number of parities stored in the memory device 250, 150 can vary. This may result in a difference in error recovery performance for recovering a data entry in response to an error (e.g., UECC) when the error occurs in the memory device 250, 150. Hereinafter, it will be explained that error recovery performance varies depending on parity group sets and location sets for data entry storage.

According to an embodiment, the parity device 234 described in FIG. 1 or a parity operation unit 146 described in FIG. 2 may require a buffer for storing all data stored in n memory dies (e.g., Die 0, Die 1, . . . , Die n−1) and the generated parity during the generation of parities (e.g., parity 0, parity 1, . . . , parity 15). The size of the buffer used by the parity device 234 or the parity operation unit 146 might become very large. If a significant amount of the limited internal resources of the memory system 210, 110 are used by the parity device 234 or the parity operation unit 146, the data input/output performance of the memory system 210, 110 might deteriorate. However, the parity device 234 or the parity operation unit 146 could reduce the size of the buffer by performing an operation for parity generation according to the order in which data is stored in the memory device 250, 150 in order to reduce the size of the buffer.

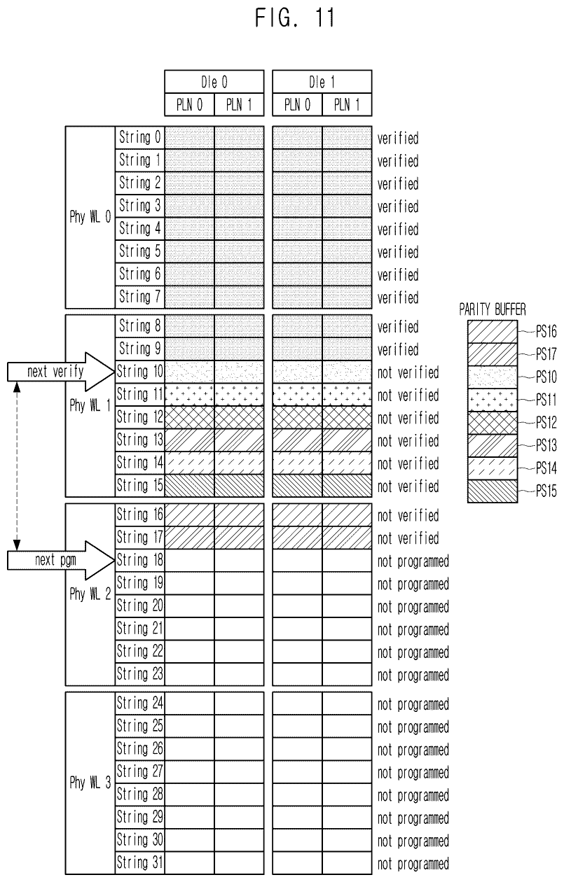

In the method of performing an operation for parity generation according to the order in which data is stored in the memory device 250, 150, the parity device 234 or the parity operation unit 146 might not store all data and generated parities stored in n memory dies (e.g., Die 0, Die 1, . . . , Die n−1) during the generation of parities (e.g., parity 0, parity 1, . . . , parity 15) in order to reduce the size of the buffer. However, if an error occurs while storing data in the memory device 250, 150, it might be difficult to recover the error because not all data and generated parities are stored. The parity device 234 or parity operation unit 146 can verify that an error occurs due to a disturbance occurring during a data storage process (e.g., a data program operation) in the memory device 250, 150 and store some parity for recovering the error in the parity buffer 238. The detailed operations of the parity device 234 or parity operation unit 146 will be described below with reference to FIGS. 11 to 15.

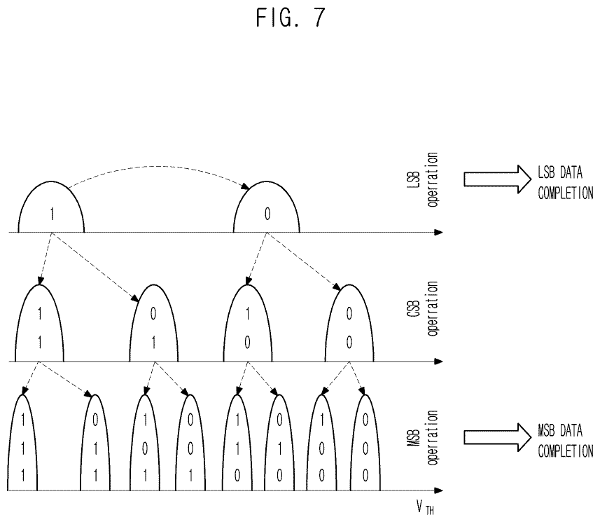

FIG. 7 illustrates an operation of programming multi-bit data in accordance with an embodiment of the present disclosure. Specifically, FIG. 7 illustrates a two-step program operation for storing 3-bit data in a non-volatile memory cell.

Referring to FIG. 7, a non-volatile memory cell can have a threshold voltage of an erased state before a data program operation is performed. When a first-step program operation is performed, LSB data may be programmed into the non-volatile memory cell. Thereafter, when a second-step program operation is performed, CSB data and MSB data can be programmed in the non-volatile memory cell. A threshold voltage of the non-volatile memory cell may have one of eight different levels after the first-step program operation and the second-step program operation are performed. Herein, eight different threshold voltage levels which the non-volatile memory cell can have can indicate three-bit data of ‘111’, ‘011’, ‘101’, ‘001’, ‘110’, ‘010’, ‘100’, and ‘000’.

The memory device 250, 150 shown in FIGS. 1 and 2 can take a long time to store multi-bit data. As described with reference to FIG. 7, when the first-step program operation is successfully completed, the memory device 250, 150 may notify a completion notice regarding the LSB data (LSB DATA COMPLETION). Thereafter, the memory device 250, 150 can program the CSB data and the MSB data through a second-step program operation. When the second-step program operation is successfully completed, the memory device 250, 150 can provide a completion notification (MSB DATA COMPLETION) for the CSB data and the MSB data.

Although it has been described in FIG. 7 that 3-bit data can be programmed in the non-volatile memory cell by a two-step program operation, in other embodiments 3-bit data can be programmed through a three-step program operation. For example, when programming in a three-step program operation, the memory device 250, 150 may transfer each completion notice regarding each of LSB data, CSB data, and MSB data.

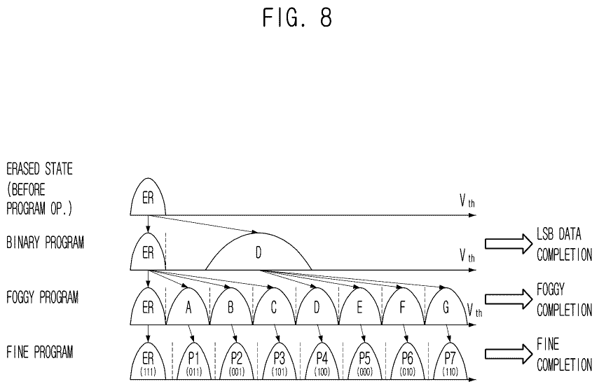

FIG. 8 illustrates programming of multi-bit data in accordance with an embodiment of the present disclosure. Specifically, FIG. 8 illustrates a two-step program operation for storing 3-bit data in a non-volatile memory cell.

Referring to FIGS. 1-2 and FIG. 8, a non-volatile memory cell can have a threshold voltage of an erased state before a data program operation is performed. The memory device 250, 150 may first perform a partial program operation based on LSB data to be stored in anon-volatile memory cell. Here, the partial program operation can include a binary programming operation in which a threshold voltage of a nonvolatile memory cell is greatly increased by using a very large ISPP step pulse. After performing the binary programming operation, the memory device 250, 150 can transfer a completion notification (LSB DATA COMPLETION) for the LSB data.

After the binary programming operation is performed, the memory device 250, 150 may program the non-volatile memory cell based on CSB and MSB data again. In this step, the threshold voltage of the non-volatile memory cell can be increased by using an ISPP step pulse smaller than that of the binary programming operation. This process can be referred to as a foggy program operation. Thereafter, the memory device 250, 150 may perform a fine program operation to narrow threshold voltage distributions of non-volatile memory cells. The fine program operation can use smaller ISPP step pulses than that used in a foggy program operation.

Unlike the binary program operation or the foggy program operation, the fine program operation can include a process of narrowing the threshold voltage distributions of the non-volatile memory cells. Accordingly, the possibility of errors can increase during the fine program operation. In an embodiment, the memory device 250, 150 can store the multi-bit data (all bit values), which are to be programmed, in the SLC buffer after the binary program operation and the foggy program operation. For another example, the memory device 250, 150 can notify completion of the foggy program operation after the foggy program operation is performed. Also, the memory device 250, 150 may notify the completion of the fine program operation (FINE COMPLETION) after the fine program is performed.

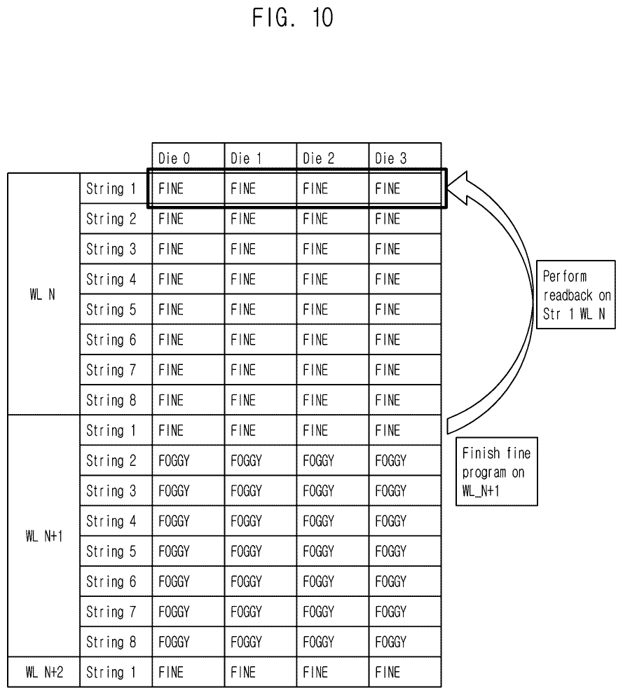

As described above, referring to FIGS. 1 to 2 and FIGS. 7 to 8, a procedure of storing the multi-bit data in the memory device 250, 150 may be performed by a plurality of step program operations. When at least some step program operations of the memory device 250, 150 are successfully completed, a completion notification could be output to the controller 230, 130. Meanwhile, the procedure of storing multi-bit data in the memory device 250, 150 might not be performed at a specific location, but may be performed simultaneously, in parallel, or sequentially within a range including plural locations. A method of verifying data stored at a specific location due to the influence of disturbance occurring in the procedure of storing multi-bit data in the memory device 250, 150 will be described later with reference to FIG. 10.

FIG. 9 illustrates an operating method of a memory system according to an embodiment of the present disclosure.

Referring to FIGS. 1 to 9, the operation method of the memory systems 210, 110 can include determining write data to be stored in a preset write range in the memory device 250, 150 (operation 412). The memory system 210, 110 can adopt a method (e.g., one-shot program, etc.) for storing a preset range or a preset amount of data in the memory device 250, 150 in order to improve data input/output performance. As described in FIGS. 7 to 8, the memory cells included in the memory device 250, 150 can store multi-bit data, and the multi-bit data can be stored through plural program operations. Accordingly, the controller 230, 130 can be configured to delay a write operation until write data to be stored in the memory device 250, 150 reaches a preset range or a preset amount. Then, the controller 230, 130 can be configured to perform a program operation to store the write data in the memory device 250, 150 after the write data reaches the preset range or the preset amount.

The operating method of the memory system 210, 110 can include performing a first write operation regarding the preset range (operation 414) and performing a second write operation regarding the preset range (operation 416). The write operation performed by the memory system 210, 110 can vary according to an embodiment. The write operation can include two or more operations, tasks, or steps. The controller 230, 130 can transmit a write command along with the preset range or the preset amount of the write data to the memory device 250, 150 to perform each of the first and second write operations.

The memory device 250, 150 can store or program data associated with, transmitted along with, the write command in a specific location (e.g., an open block, etc.). After data program is completed, the memory device 250, 150 can notify the controller 230, 130 that a program operation corresponding to the write command is completed. Specifically, at each stage or task of the program operation, the voltage supply circuit 170 in the memory device 250, 150 can supply plural program pulses to the memory cells included in the location where the data is stored. After programming the data in each memory cell, the memory device 250, 150 can apply a verification voltage to check whether the programmed data is normally stored in each memory cell. When it is determined that the data is normally stored, the memory device 250, 150 can notify the controller 230, 130 of the completion of the program operation. The controller 230, 130 can sequentially transmit plural write commands along with plural write data to the memory device 250, 150. The memory device 250, 150 can sequentially store the sequentially transmitted write data according to the program method described in FIGS. 7 and 8.

The operation method of the memory system 210, 110 can include determining a next write/program range (operation 418). The controller 230, 130 that has received a notification from the memory device 250, 150 that data has been successfully stored or programmed for the preset write range can determine the next write/program range (operation 418).

As described above, the memory system 210, 110 can generate parity and store the parity in a procedure of storing a preset unit of data in the memory device 250, 150. As described in FIG. 6, the controller 230, 130 can sequentially transfer a plurality of data corresponding to 16 parities to ‘n’ number of memory dies (Die 0, Die 1, . . . , Die n−1). The memory device 250, 150 can store the plurality of data and the 16 parities sequentially transferred from the controller 230, 130 to the ‘n’ memory dies (Die 0, Die 1, . . . , Die n−1).

The operating method of the memory system 210, 110 can include reading data in a range in which writing has been completed (operation 422). As described in FIG. 3, the memory device 250, 150 can include a 2D or 3D cell array in which a plurality of memory cells are integrated. For example, while performing an operation of programming data to a first location of the memory device 250, 150, a program disturb can occur in another memory cell located at a second location which is included within a preset range around the first location. Memory cells affected by the program disturb can include at least some memory cells that have already completed a write operation to store data. When the memory cell is affected by the program disturb after a write operation that applies plural program pulses and at least one verification pulse to a specific memory cell is completed, the data stored in the memory cell might be changed or distorted. In order to check whether the data is changed or distorted and an error occurs in the data due to the program disturb, the controller 230, 130 can read the data stored in the second location (operation 422).

Here, the first location is the location where the most recent program operation was completed, and the second location can be any location within the range where the program disturb may occur due to the program operation of the first location. For example, if the first location is the Nth page of the open memory block, the second location could be the (N−K)th page of the open memory block (herein, both N and K are natural numbers). The first location and the second location will be described later with reference to FIGS. 10 and 11.

The operating method of the memory system 210, 110 can include verifying data stored in a previous range based on a parity (operation 424). When storing data in the memory device 250, 150, the controller 230, 130 can generate a parity and check whether data stored in the memory device 250, 150 includes an error based on the generated parity. According to an embodiment, the parity used by the controller 230, 130 can be different from the parities (e.g., parity 0, parity 1, . . . , parity 15) described in FIG. 6. The parities (e.g., parity 0, parity 1, . . . , parity 15) described in FIG. 6 are a kind of information stored or programmed in the memory device 250, 150, like the data. On the other hand, the parity used by the controller 230, 130 in FIG. 9 can be similar to the parity described in FIG. 5.

For example, as described in FIG. 6, in a procedure of storing the plurality of data corresponding to 16 parities (e.g., parity 0, parity 1, . . . , parity 15) in the n memory dies (e.g., Die 0, Die 1, . . . , Die n−1), a plurality of first data (e.g., page 0) can be stored first in a position corresponding to a first string (e.g., String 0) of a first word line WL 0 in the n memory dies (e.g., Die 0, Die 1, . . . , Die n−1). Here, the plurality of first data (e.g., page 0) are included in a first data superblock (e.g., s-page 0). The first data superblock (e.g., s-page 0) can correspond to one chipkill unit described in FIG. 5. The controller 230, 130 can perform an XOR operation on the plurality of first data (e.g., page 0) and temporarily store the performed result of the XOR operation. The temporarily stored value can be later used to generate the first parity (e.g., parity 0).

Afterwards, a plurality of second data (e.g., page 1) can be stored in a location corresponding to a second string (e.g., String 1) of the first word line WL0 in n memory dies (e.g., Die 0, Die 1, . . . , Die n−1). The controller 230, 130 can perform an XOR operation on the plurality of second data (e.g., page 1) and temporarily store a result of the operation. The temporarily stored value can be later used to generate the second parity (e.g., parity 1).

The memory device 250, 150 can store the data in a preset location in an order transmitted from the controller 230, 130. When the memory device 250, 150 stores a plurality of 17th data (e.g., page 16) included in the 16th data superblock (e.g., s-page 16), the controller 230, 130 can perform an XOR operation on the result of the XOR operation for the first data superblock (e.g., s-page 0) that is temporarily stored and the result of the XOR operation for the plurality of 17th data (e.g., page 16). The result of this XOR operation can be later used to generate the first parity (e.g., parity 0). When the controller 230, 130 stores all of the XOR operation results generated in the middle with respect to the first parity (e.g., parity 0), the controller 230, 130 should allocate a significant amount of the buffer to storing the parity operation and its results. Therefore, the controller 230, 130 does not store the XOR operation results generated in the middle, and after performing an XOR operation on the result of the XOR operation for the first data superblock (e.g., s-page 0) and the result of the XOR operation for the 17th data superblock (e.g., s-page 16), the controller 230, 130 can store the result of the XOR operation. The controller 230, 130 does not store the XOR operations regarding the first data superblock (e.g., s-page 0) and the 17th data superblock (e.g., s-page 16), which were previously performed.

While a program operation for the 33rd data superblock (e.g., s-page 32) related to the first parity (e.g., parity 0) is performed, data might not be stored normally in the memory device 250, 150 so that the program operation might fail. Because the results of the XOR operation for each of the first data superblock (e.g., s-page 0) and the seventeenth data superblock (e.g., s-page 16) have already been discarded, the memory device 250, 150 might have to re-perform the program operation for the first data superblock (e.g., s-page 0) in order to recover the failed program operation. This is because it is difficult to determine whether the data stored in the location where the program has already been completed contains an error due to a disturb that occurred during the program operation. This situation could significantly deteriorate the operating performance of the memory system 210, 110. However, if the controller 230, 130 does not discard a result of the XOR operation for the data superblock that falls within the range that might affect the disturb that occurs during the program operation, even if the result is not the final value (e.g., 16 parities, e.g., parity 0, parity 1, . . . , parity 15) to be stored or programmed in the memory device 250, 150, the controller 230, 130 can verify the reliability of the data already stored in the memory device 250, 150, and this verification may be used to recover a failed program operation. The operations of the memory system 210, 110 will be described later with reference to FIGS. 10 to 15.

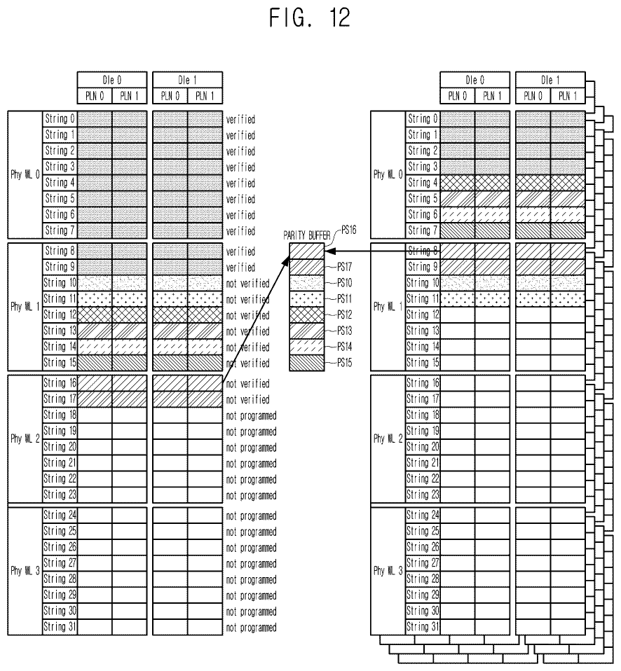

After the controller 230, 130 in the memory system 210, 110 verifies the data stored in the memory device 250, 150 based on the parity, the verification result data might have no errors. When there is no error in the data, the controller 230, 130 no longer needs to store parity information corresponding to the error-free data. The controller 230, 130 can store other data in the memory device 250, 150 and overwrite the location where the parity information for the data is stored, which no longer needs to be stored. These operations will be described later with reference to FIGS. 11 and 12.

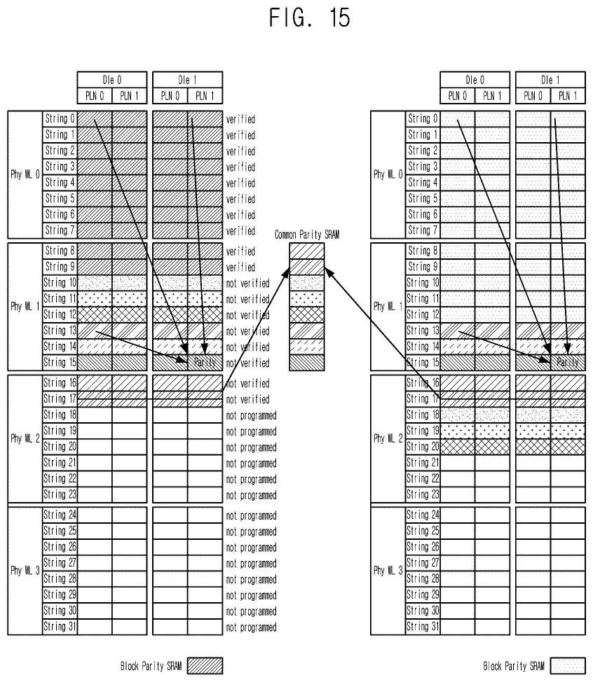

After the controller 230, 130 in the memory system 210, 110 verifies the data stored in the memory device 250, 150 based on the parity, the verification result data can include an error. The operation method of the memory system 210, 110 can include performing a recovery operation according to the verification result (operation 426). For example, it could be possible to check whether there is an error in a specific data superblock unit. Based on the parity information corresponding to the specific data superblock, it could be determined that there is an error in the specific data superblock. The controller 230, 130 within the memory system 210, 110 can recover an error within a specific data superblock based on parity information and store the recovered data in the memory device 250, 150. According to an embodiment, the recovered data can be stored in a memory block other than the memory block in which the specific data superblock was stored. The recovery operation according to the verification result will be described below with reference to FIG. 15.

FIG. 10 illustrates a method of verifying data stored in a memory device according to an embodiment of the present disclosure.

Referring to FIGS. 1 to 10, data can be stored in a plurality of memory dies (e.g., Die0, Die1, Die2, Die3) within the memory device 250, 150. For example, a foggy program operation (FOGGY) and a fine program operation (FINE) have already completed in a plurality of regions (e.g., String1, String2, String3, String4, String5, String6, String7, String8) connected to the Nth word line (e.g., WL N). In some regions (e.g., String1) connected to the (N+1)th word line (e.g., WL N+1), the foggy program operation (FOGGY) and the fine program operation (FINE) have already been completed. However, in other regions (e.g., String2, String3, String4, String5, String6, String7, String8), the foggy program operation (FOGGY) has been completed and the fine program operation (FINE) has not been completed.

The memory system 210, 110 has completed the FINE program operation in some regions (e.g., String1) connected to the (N+1)th word line (e.g., WL N+1), but the verification operation using parity information can be performed on some regions (e.g., String1) connected to the Nth word line (e.g., WL N). Here, some regions (e.g., String1) connected to the Nth word line (e.g., WL N) that are the target of the verification operation have already completed programming all bits of data stored in the memory cell. However, memory cells in some regions (e.g., String1) can fall within a range which might be affected by the disturb caused by the FINE program operation (FINE) to be performed at the (N+1)th word line (e.g., WL N+1).

Here, correlation or relationship between a location where the program operation is performed and a location where the verification operation is performed can be determined based on structural or operational characteristics of the memory device 250, 150. For example, as an integration degree of the cell array in the memory device 250, 150 is lower, a range of influence due to disturbance that occurs during the program operation might be smaller, narrower or decreased. Conversely, as the integration degree of the cell array of the memory device 250, 150 is higher, the range of influence due to the disturbance that occurs during the program operation might be larger, wider or increased. In addition, the range of influence due to the disturbance can be different depending on whether the cell array of the memory device 250, 150 is fabricated in the form of a 2D or 3D structure. Furthermore, the range of influence due to the disturbance can vary depending on how to perform a program operation within the memory device 250, 150 or which order of locations or areas program operations or tasks are performed at.

According to an embodiment, a range of influence due to the disturbance during the program operation can be determined through a test process after manufacturing the memory device 250, 150. According to an embodiment, a voltage used for the verification operation output from the voltage supply circuit 170 can be determined based on the operating characteristics of the memory device 250, 150. For example, while performing a program operation at a specific location (e.g., String0), a phenomenon in which the threshold voltage distribution increases in the erased state can also occur at an adjacent location (e.g., String1). The voltage distribution of the memory cells at the surrounding locations can move in a direction of increasing the voltage distribution. On the other hand, a memory cell at a location close to a word line (e.g., Erased WL) on which a program operation is not performed and which is connected to a memory cell in the erased state can have a relatively low threshold voltage distribution. The voltage supply circuit 170 can apply different levels of voltage to the memory cell based on a location where the verification operation is performed. For example, when reading data stored at a location less affected by disturbance or interference, a read reference voltage (e.g., a read bias offset) can be set lower. Conversely, when reading data stored at a location greatly affected by disturbance or interference, the read reference voltage (e.g., the read bias offset) can be set higher.

FIG. 10 illustrates an example of programming data in string units connected to each word line, and verifying data stored in a string (e.g., WL N, String1) connected to a previous word line but arranged in a same column direction as the string when the program of the string connected to a specific word line (e.g., WL N+1, String1) is completed. In this case, a difference or a gap between locations performed by the program operations of the string on which the program operation is performed and the string on which the verification operation is performed is 8. The controller 230, 130 can be configured to allocate an area or a space capable of storing 9 pieces of parity information.

For example, when the fine program operation (FINE) is completed in a portion (e.g., String1) connected to the (N+1)th word line (e.g., WL N+1), the controller 230, 130 can be configured to store parity information for data stored in a portion (e.g., String1) connected to the (N+1)th word line (e.g., WL N+1). Thereafter, the controller 230, 130 can perform a verification operation for some area (e.g., String1) connected to the Nth word line (e.g., WL N) based on already-stored parity information. When there is no error in the data stored in some area (e.g., String1) connected to the Nth word line (e.g., WL N), the controller 230, 130 might not need to maintain the parity information for the data stored in some area (e.g., String1) connected to the Nth word line (e.g., WL N). When the fine program operation (FINE) is completed in another area (e.g., String2) connected to the (N+1)th word line (e.g., WL N+1), the controller 230, 130 can be configured to generate parity information for the data stored in some area (e.g., String2) connected to the (N+1)th word line (e.g., WL N+1) and then overwrite the parity information for the data stored in some area (e.g., String1) connected to the Nth word line (e.g., WL N) at the stored location. To perform these verification operations, an area for parity information for verification operations might be sufficient when it is set to store nine pieces of parity information in a volatile memory.

FIG. 11 illustrates a program operation and a verification operation performed by a memory system according to an embodiment of the present disclosure.

Referring to FIGS. 1 to 2 and FIG. 11, each of a plurality of dies Die0, Die1 in the memory device 250, 150 can include a plurality of memory planes PLN 0, PLN1. Each word line (e.g., Phy WL 0, Phy WL 1, Phy WL 2, Phy WL 3) can be connected to a storage area divided into eight strings (e.g., String0-7, String8-15, String16-23, String24-31). Although the physical structure of the memory device 250, 150 might be different, FIG. 11 describes a plurality of storage areas arranged in a program order.

In FIG. 11, data has been programmed up to the 10th string (e.g., String9) of the first word line (e.g., Phy WL 1), and a verification operation has also been performed (verified) for the corresponding area. From the 11th string (e.g., String 10) to the 18th string (e.g., String 17), other data is stored, but a verification operation has not yet been performed (not verified). After the 19th string (e.g., String 18), other data is not stored (not programmed). In this case, the location where the next data is to be programmed (e.g., Next PGM) is the 19th string (e.g., String 18), and the location where the next verification operation is to be performed (e.g., Next Verify) is the 11th string (e.g., String 10).

Further, 8 pieces of parity information (e.g., PS10, PS11, PS12, PS13, PS14, PS15, PS16, PS17) are stored in the parity buffer. The 11th parity information (e.g., PS10) can be a result of performing an XOR operation on four pieces of data stored in the 11th string (e.g., String 10) of the plurality of memory planes PLN0, PLN1 included in each of the plurality of dies Die0, Die1. The controller 230, 130 can read four pieces of data stored in the 11th string (e.g., String 10) of the plurality of memory planes PLN0, PLN1 included in each of the plurality of dies Die0, Die1. Then, the controller 230, 130 can use the 11th parity information (e.g., PS10) stored in the parity buffer to check whether there is an error in the four pieces of data stored in the 11th string (e.g., String 10).

When there is no error in the four pieces of data stored in the 11th string (e.g., String 10), the controller 230, 130 does not need to store or keep the 11th parity information (e.g., PS10) in the parity buffer any more. The controller 230, 130 can perform a program operation in the 19th string (e.g., String 18) and overwrite the 19th parity information, which is a result of an XOR operation on other four pieces of data stored in the 19th string (e.g., String 18), in the location where the 11th parity information (e.g., PS10) has been stored.

When there is an error in at least one of the four pieces of data stored in the 11th string (e.g., String 10), the controller 230, 130 can recover the errored data based on the 11th parity information (e.g., PS10).

Referring to FIG. 11, it is possible to verify and recover whether an error occurs due to the influence of a disturbance caused by a program operation during the procedure of storing a large amount of data in the memory device 250, 150. In these operations, because only eight pieces of parity information (e.g., PS10, PS11, PS12, PS13, PS14, PS15, PS16, PS17) are stored in the parity buffer, the controller 230, 130 could reduce an area allocated and used for parity-related operations from limited internal resources.

FIG. 12 illustrates a method of using parity information of a memory system according to an embodiment of the present disclosure. FIG. 12 is similar to the program operation and verification operation described in FIG. 11, but in FIG. 12 the location where data is stored varies based on plural open memory blocks.

Referring to FIG. 12, the memory device 250, 150 can include plural storage devices. Each of the plural storage devices can include an open memory block for storing data. The parity information generated by the controller 230, 130 can be used for verifying and recovering whether an error occurs due to disturbance or interference in the procedure of storing or programming a large amount of data.

The controller 230, 130 can store a preset number of parity information (e.g., PS10, PS11, PS12, PS13, PS14, PS15, PS16, PS17) to perform a verification operation. The number of parity information corresponds to the difference or gap between a location where the program operation is performed and a location where the verification operation is performed.

The controller 230, 130 can use parity information for plural open memory blocks. Even if the locations of open memory blocks or the locations of word lines or strings within the open memory blocks are different in the plural storage devices, the controller 230, 130 can know locations of data associated with the parity information. For example, in response to a program method and an operating method (or policy, scheme) of the open memory block, the controller 230, 130 can group a preset number of data and perform an XOR operation on the data belonging to the corresponding group. In addition, the preset number of data is sequentially transferred to the parity device 234 or the parity operation unit 146 before being stored in the memory device 250, 150. The parity device 234 or the parity operation unit 146 can perform an XOR operation on the sequentially transferred data.

For the verification operation, the controller 230, 130 can read data associated with parity information from the memory device 250, 150 in a reverse order of the order transmitted for the XOR operation performed by the parity device 234 or the parity operation unit 146. Based on a verification operation of reading in the reverse order for the program operation through the parity device 234 or the parity operation unit 146 and performing the XOR operation on pieces of read data, the controller 230, 130 can be configured to determine whether the pieces of read data associated with the corresponding parity information includes an error.

According to an embodiment, when the controller 230, 130 can know the location information (e.g., logical address, physical address, etc.) for the plurality of data corresponding to each parity information, the limitation on the location where the plurality of data are stored in the memory device 250, 150 could be reduced. As illustrated in FIG. 12, pieces of data related to the same parity information can be stored in different locations (e.g., different word lines, different strings, etc.) within an open memory block.

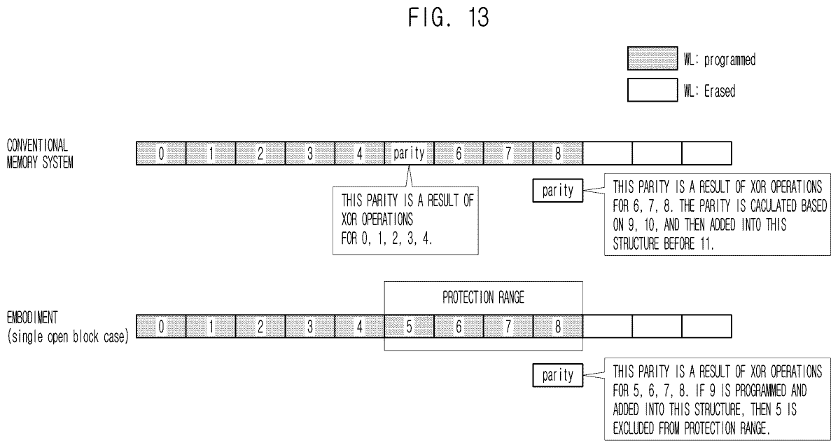

FIG. 13 illustrates a parity generation operation of a memory system according to an embodiment of the present disclosure. Specifically, FIG. 13 compares and describes a parity generation and storage method in a conventional memory system with a parity generation and storage method in a memory system according to an embodiment of the present disclosure.

In a conventional memory system performing an XOR operation on preset pieces of data, a generated parity, e.g., a result of the XOR operation, could be stored in a non-volatile memory device. For example, in a conventional memory system, after storing five pieces of data (e.g., 0, 1, 2, 3, 4) in the non-volatile memory device, a parity (PARITY) which is a result of the XOR operation on the five pieces of data (e.g., 0, 1, 2, 3, 4) could be stored in a next area. Thereafter, the conventional memory system can store other five pieces of data (6, 7, 8, etc.) in the non-volatile memory device and then store the parity for the corresponding data in a next area. The conventional memory system can perform a verification operation in a unit of five pieces of data, and thus, 1/6 of the storage areas in the memory device could be filled with a parity.

As described in FIGS. 5 and 6, when storing a large amount of data, the conventional memory system can store one parity corresponding to 63, 127, or etc. pieces of data. However, in this case, the verification operation can also be performed in a unit of 63, 127 or etc. pieces of data. While storing a large amount of data in a memory device, the program operation is repeatedly performed in a small unit (e.g., a minimum page unit). In order to check for data distortion due to interference or disturb caused by program operations, the conventional memory system stores more parities in the non-volatile memory device.

In the memory system 210, 110 according to an embodiment of the present disclosure and unlike the conventional memory system, parity information used to check for data distortion due to interference or disturb caused by program operations repeatedly performed in a small unit (e.g., a minimum page unit) might not be stored in the memory device 250, 150. The memory system 210, 110 can sequentially store nine data (e.g., 0, 1, 2, 3, 4, 5, 6, 7, 8) in the memory device 250, 150. After storing the ninth pieces of data (e.g., 8) in the memory device 250, 150, a verification operation can be performed on the fifth pieces of data (e.g., 4). When there is no error in the fifth pieces of data (e.g., 4) as a result of the verification operation, parity information PARITY only for the sixth pieces of data (e.g., 5) to the ninth pieces of data (e.g., 8), not the fifth pieces of data (e.g., 4), could be kept or maintained in the parity buffer 238. The memory system 210, 110 does not store parities for the first pieces of data (e.g., 0) to the fifth pieces of data (e.g., 4) in the memory device 250, 150, which might be free from interference or disturb caused by program operations that are repeatedly performed in the small unit (e.g., the minimum page unit).

Through this procedure, more space in the memory device 250, 150 could be used to store non-parity data. In addition, because a verification operation corresponding to a program operation that is repeatedly performed in the small unit (e.g., the minimum page unit) could be performed at odd times even while storing a large amount of data in the memory device, reliability of the data stored in the memory device 250, 150 could be improved. In addition, because parity information limited to a range affected by interference or disturb due to a program operation that is repeatedly performed in the small unit (e.g., the minimum page unit) is temporarily stored in the parity buffer 238, limited internal resources of the controller 230, 130 could be used efficiently.

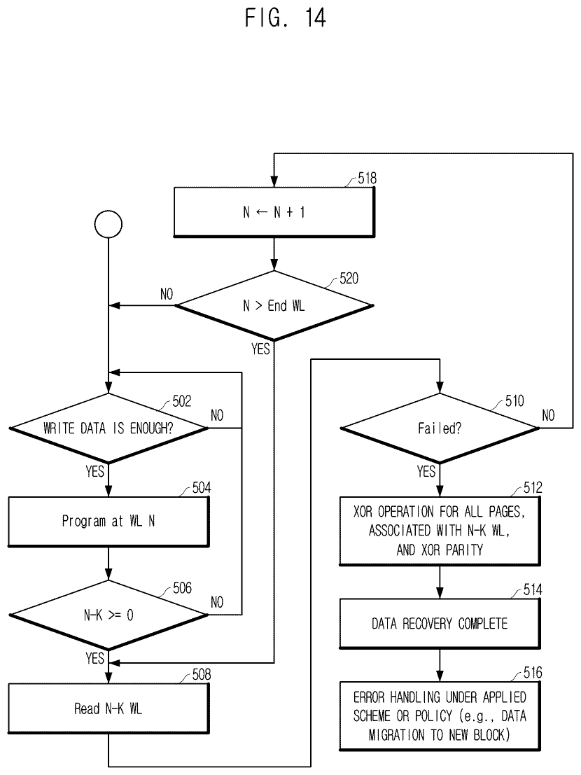

FIG. 14 illustrates an operation method of a memory system according to an embodiment of the present disclosure. Specifically, FIG. 14 describes an operation for storing data in a memory system and an operation for recovering data after an error.

Referring to FIG. 14, memory systems 210, 110 can check whether there is sufficient data to be stored in the memory device 250, 150 (operation 502). The memory cell in the memory device 250, 150 can store multi-bit data. The program operation can be performed in a preset unit or range. When an amount of data transmitted by the host 202, 102, which is an external device, to be stored in the memory system 210, 110 does not reach a preset size (NO of operation 502), the memory system 210, 110 could delay execution of the program operation until a sufficient amount of data is input and gathered.

According to an embodiment, the memory system 210, 110 could perform the program operation by adding dummy data when there is an insufficient amount of data.

When there is enough data to be stored in the memory device 250, 150, the memory system 210, 110 can program pieces of data in write locations or a preset range, e.g., the Nth word line (e.g., WL N), within the open memory block (operation 504). At this time, the memory device 250, 150 can generate parity information corresponding to the pieces of data to be programmed. Here, the parity information could be a result of an XOR operation on the pieces of data to be programmed.

After programming pieces of data in the memory device 250, 150, the memory system 210, 110 can check whether a value (e.g., N−K) obtained by subtracting a preset value (e.g., K) from the Nth word line (e.g., WL N), which is the location where the data is programmed, is greater than 0 (operation 506). When the deducted value (e.g., N−K) is less than 0 (NO of operation 506), the memory system 210, 110 can check whether there is enough data to be stored in a next location (e.g., (N+1)th word line) (operation 502). Here, a preset value (e.g., K) can indicate a difference between locations of the program operation and the verification operation. The preset value (e.g., K) can be determined according to a range and an amount of data in which the program operation may fail or the already stored data might be distorted due to interference or disturbance caused by the program operation. For example, when 8 strings are connected to a single word line, the word line could be damaged or a problem occurs in the word line. Reliability of the pieces of data stored in all 8 strings might be reduced. Therefore, the preset value (e.g., K) can be set to 8 or a higher value (e.g., 9=8+1).

Here, when the deducted value (e.g., N−K) is less than 0 (NO of operation 506), the memory system 210, 110 can delay execution of the verification operation shortly after data was stored in an open memory block within the memory device 250, 150. When there is a high possibility that the already stored data will be distorted by the program operation to be performed in the future, the memory system 210, 110 could delay the verification operation for the already stored data.

When the deducted value (e.g., N−K) is greater than 0 (YES of operation 506), the memory device 250, 150 can read the data in the storage area or space connected to the (N−K)th word line for the verification operation (operation 508).

The memory system 210, 110 can check whether the data read from the storage area or space connected to the (N−K)th word line includes an error, based on the parity information (operation 510). When there is no error in the data (NO of operation 510), the memory system 210, 110 can change the location where other data is to be programmed (operation 518). For example, when the data is programmed in the storage area or space connected to the Nth word line (e.g., WL N), the memory system 210, 110 can control or process other data to be stored in the storage area or space connected to the (N+1)th word line.

The memory system 210, 110 can check whether the location where other data is to be stored is a same open memory block (operation 520). When word lines associated with the locations for the other data, i.e., next locations, are less than the last word line (e.g., END WL) of the open memory block (NO of operation 520), the memory system 210, 110 can check whether a sufficient amount of data to be stored in the next locations is gathered (operation 502).

When at least some of the next locations are beyond the last word line (e.g., END WL) (YES of operation 520), the memory system 210, 110 can prepare a new open memory block. In addition, the memory system 210, 110 can read data at a location in the open memory block where the verification operation has not yet been completed (operation 508). When a previous verification operation is performed for data stored in a storage area or space connected to the (N−K)th word line, the verification operation is performed by the memory system 210, 110 for data stored in a storage area or space connected to the (N+1−K)th word line (operation 508), after N is increased by 1 (N←N+1, operation 518).

As described above, when no error is found in the verification operation, the memory system 210, 110 can be configured to sequentially increase the location of the program operation and the location of the verification operation in the open memory block in the memory device 250, 150, store or program other data in the memory device 250, 150, and perform the verification operation on the programmed data.

The memory system 210, 110 can check whether the data read from the storage space connected to the (N−K)th word line include an error, using parity information (operation 510). There may be an error in the data (YES of operation 510). The memory system 210, 110 can read the data where the error occurred, that is, the data stored in the storage area or space connected to the (N−K)th word line, and the data stored in all other locations (e.g., PAGE) involved in the generation of the parity information (operation 512). The memory system 210, 110 could sequentially perform an XOR operation on the read data (operation 512).

The memory system 210, 110 can recover or restore data with errors through the XOR operation (operation 514).

The memory system 210, 110 can store the recovered data in a location determined based on an algorithm, a scheme, or a policy associated with the recovery operation (operation 516). For example, recovered data might be stored in a memory block other than the memory block including the data in which the error occurred. According to an embodiment, the memory system 210, 110 can also migrate all other data, stored in the memory block but even determined to have no errors, to another memory block for data safety.

FIG. 15 illustrates a data recovery operation of a memory system according to an embodiment of the present disclosure. Specifically, FIG. 15 describes a recovery operation that can be performed based on two types of parities generated by the memory system.

Referring to FIGS. 1 to 15, memory systems 210, 110 can store data in a plurality of memory devices 250, 150. Each of the plurality of memory devices 250, 150 can include a plurality of memory dies Die0, Die1. The plurality of memory dies Die0, Die1 can include a plurality of memory planes PLN0, PLN1. A plurality of storage areas or spaces (e.g., String 0, String 1, String 2, String 3, String 4, String 5, String 6, String 7) can be coupled to each of the plurality of word lines (e.g., Phy WL 0, Phy WL 1, Phy WL 2, Phy WL 3).

The memory system 210, 110 can be configured to generate two types of parities. First, a first type parity (e.g., Parity) could be stored in a 16th string (e.g., String 15) connected to a second word line (e.g., Phy WL 1) in a second memory plane PLN1 of a second memory die Die1 in the memory device 250, 150. Here, the first type parity (e.g., Parity) can be a result of an XOR operation for a plurality of data stored in the first to 16th strings (e.g., String 0 to 15) coupled to the first and second word lines (e.g., Phy WL 0, Phy WL 1) of the first and second memory dies Die 0, Die 1. The first type parity can correspond to the parities (e.g., parity 0, parity 1, . . . , parity 15) described in FIG. 6.

The memory system 210, 110 can generate and store a second type parity in a common parity buffer (e.g., Common Parity SRAM). Here, the second type parity can correspond to the parity information (e.g., PS10, PS11, PS12, PS13, PS14, PS15, PS16, PS17) described in FIGS. 11 and 12. For example, the second type parity can be a result of an XOR operation for a plurality of data stored in the 18th string (e.g., String 17) in the plurality of memory devices 250, 150. The second type parity can include a result of an XOR operation for data in a state where the program operation of the data is completed but the verification operation is not performed (not verified).

FIG. 15 illustrates a plurality of data associated with the second type parity stored in the common parity SRAM in a same pattern. According to an embodiment, the storage location of data associated with the second type parity can be a same location, e.g., the 18th string (e.g., String 17), within the plurality of memory devices 250, 150 or can be different locations, e.g., the 10th string (e.g., String 10) and the 19th string (e.g., String 18), within the plurality of memory devices 250, 150.

The memory system 210, 110 can use the first type parity and the second type parity to check whether there is an error included in the plurality of data stored in the plurality of memory devices 250, 150 and to repair the detected error. The plurality of data associated with the first type parity and the second type parity can be different from each other. The first type parity and the second type parity can include XOR operation results for data stored in different storage areas.

The first type parity can be associated with a plurality of data stored in the memory device 250, 150. The memory system 210, 110 can perform a read operation on at least some of the plurality of data stored in the memory device 250, 150. When data stored in a specific location cannot be read during the read operation (e.g., if an UECC occurs), the memory system 210, 110 can read the plurality of data associated with the specific location where the error occurred and the first type parity and, then, perform an XOR operation on the plurality of data and the first type parity to recover errored data such as the UECC.

The second type parity can be used for performing a verification operation to check for data distortion due to interference or disturbance caused by a program operation that stores data in the memory device 250, 150. The second type parity might not include parity information associated with data stored in a location outside a range of interference or disturb caused by the program operation. That is, a parity corresponding to the location where the verification operation has already been completed might not be stored in the common parity buffer (e.g., Common Parity SRAM, Block Parity SRAM). Therefore, the number of second type parities can be determined based on the operating characteristics (e.g., the range of interference or disturb) of the memory device 250, 150.

As described above, the memory system 210, 110 according to an embodiment of the present disclosure can generate different types of parities and store at least some of the different types of parities in the memory device 250, 150. Based on the different types of parities, the memory system 210, 110 can improve the reliability of data stored in the memory device 250, 150. In particular, when storing a large amount of data in a memory device 250, 150, the memory system 210, 110 can perform a program operation for storing data belonging to a preset range or unit, and perform a verification operation for a location different from the location where the program operation is performed, thereby improving the reliability of the data stored in the memory device 250, 150. In addition, when an error is found through the verification operation, the memory system 210, 110 can perform a recovery operation for at least some of the large amount of data. Through this procedure, operational efficiency or safety of the memory system 210, 110 could be improved.

A memory device or a memory system according to an embodiment of the present disclosure can improve safety of a write operation by using relatively fewer resources in a procedure of storing a large amount of data in the memory device, thereby improving operational reliability of the memory system.

In addition, as the number of bits of data that can be stored in a memory cell increases, the number of program operations performed on the memory cell increases. The memory device or the memory system according to an embodiment of the present disclosure can improve performance by efficiently using internal resources of the memory system, because the increase in resources required to verify the corresponding program operation through parity is reduced compared to the increase in the number of program operations performed on the memory cell.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments, may transform the computer, processor, controller, or other signal processing device into a special-purpose processor for performing the methods herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, controller, or other signal processing device which is to execute the code or instructions for performing the method embodiments or operations of the apparatus embodiments herein.

The controllers, processors, control circuitry, devices, modules, units, multiplexers, logic, interfaces, decoders, drivers, generators and other signal generating and signal processing features of the embodiments disclosed herein may be implemented, for example, in non-transitory logic that may include hardware, software, or both. When implemented at least partially in hardware, the controllers, processors, control circuitry, devices, modules, units, multiplexers, logic, interfaces, decoders, drivers, generators and other signal generating and signal processing features may be, for example, any of a variety of integrated circuits including but not limited to an application-specific integrated circuit, a field-programmable gate array, a combination of logic gates, a system-on-chip, a microprocessor, or another type of processing or control circuit.

When implemented at least partially in software, the controllers, processors, control circuitry, devices, modules, units, multiplexers, logic, interfaces, decoders, drivers, generators and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments, may transform the computer, processor, controller, or other signal processing device into a special-purpose processor for performing the methods described herein.

While the present teachings have been illustrated and described with respect to specific embodiments, it will be apparent to those skilled in the art in light of the present disclosure that various changes and modifications may be made without departing from the spirit and scope of the disclosure as defined in the following claims. Furthermore, the embodiments may be combined to form additional embodiments.

What is claimed is:

1. A memory system, comprising:
a memory device including a plurality of data storage areas; and
a controller configured to distribute and store a plurality of first data in a first range among the plurality of data storage areas, generate a first parity corresponding to the plurality of first data, read the plurality of first data from the first range before distributing and storing a plurality of second data in a second range spaced apart from the first range by a preset distance, perform a verification operation based on the first parity, and overwrite a second parity, corresponding to the plurality of second data in a location where the first parity is stored, based on a verification result.

2. The memory system according to claim 1, wherein the plurality of first data and the plurality of second data, respectively stored in the first range and the second range, are the same size.

3. The memory system according to claim 1, wherein the first range includes at least one page included in each of different memory dies, different memory planes, or different memory blocks.

4. The memory system according to claim 1, wherein the first parity is a result of an exclusive OR (XOR) operation on the plurality of first data.

5. The memory system according to claim 1, wherein the first range and the second range include at least one page included in a same memory die, a same memory plane, or a same memory block.

6. The memory system according to claim 1, wherein the preset distance is determined based on a range of program interference or program disturb occurring in the memory device.

7. The memory system according to claim 1, wherein each memory cell included in the memory device stores multi-bit data, and
wherein the controller is configured to complete a plurality of program operations for distributing and storing the multi-bit data in the first range before distributing and storing the plurality of second data in the second range.

8. The memory system according to claim 1, wherein, when there is no error in the plurality of first data in a result of the verification operation, the controller is configured to store the plurality of second data in the second range in a preset distributed manner and overwrite the second parity in the location after storing the plurality of second data.

9. The memory system according to claim 1, wherein, when there is an error in the plurality of first data in a result of the verification operation, the controller is configured to store the plurality of second data in a preset distributed manner and perform a recovery operation regarding the plurality of first data before overwriting the second parity in the location.

10. The memory system according to claim 9, wherein the controller is configured to, while recovering the plurality of first data, store the recovered plurality of first data in a first memory block other than a second memory block where the plurality of first data is stored.

11. The memory system according to claim 1, wherein the controller is configured to generate a parity corresponding to a parity group including the plurality of first data and the plurality of second data, stored in the first range and the second range, and store the parity in the memory device.

12. A memory system, comprising:
a memory device including an open memory block that sequentially stores a plurality of data corresponding to a plurality of program commands; and
a controller configured to transmit, to the memory device, a read command for second data stored at a second location which is spaced apart from a first location in the open memory block by a preset distance to perform a verification operation on the second data, before transmitting a first program command for first data to be stored at the first location in the open memory block to the memory device.

13. The memory system according to claim 12, wherein the first data and the second data stored at the first location and the second location have the same size.

14. The memory system according to claim 13, wherein the first location and the second location individually include at least one page.

15. The memory system according to claim 12, wherein the preset distance is determined based on a range of program interference or program disturb occurring in the memory device.

16. The memory system according to claim 12, wherein each memory cell included in the open memory block stores multi-bit data, and
wherein the controller is configured to complete a plurality of program operations for distributing and storing the multi-bit data in the second location before distributing and storing the first data in the first location.

17. The memory system according to claim 12, wherein the controller is configured to:
store a second parity related to the second data for the verification operation; and
overwrite, based on a result of the verification operation, a first parity related to the first data in a location where the second parity is stored.

18. The memory system according to claim 17, wherein the controller is configured to:
distribute and store the first data in a first range of the memory device, when there is no error in the second data as a result of the verification operation, and overwrite the first parity in the location where the second parity is stored; and
distribute and store the first data in the first range, when there is an error in the second data as the result of the verification operation, and perform a recovery operation on the second data before overwriting the first parity in the location where the second parity is stored.

19. A method for operating a memory system, comprising:
determining first data to be stored in a first location in a memory device;
reading second data stored in a second location spaced apart from the first location by a preset distance;
checking whether the second data has an error based on a second parity associated with the second data; and
storing the first data in the first location and overwriting a first parity associated with the first data in a location where the second parity is stored, when there is no error in the second data.

20. The method according to claim 19, further comprising:
recovering the second data before storing the first data in the first location, when there is an error in the second data; and
determining the preset distance based on a range of program interference or program disturb occurring in the memory device.
